(19) United States
(12) Patent Application Publication
(10) Pub. No.: US 2022/0177651 A1
(43) Pub. Date: Jun. 9, 2022

(54) CROSSLINKABLE SILOXANE COMPOUNDS FOR THE PREPARATION OF DIELECTRIC MATERIALS

(71) Applicant: Merck Patent GmbH, Darmstadt (DE)

(72) Inventors: Karsten KOPPE, Darmstadt (DE); Jens EICHHORN, Reinheim (DE); Ben JEFFERY, Poole (GB); Alex DAVIS, Eastleigh (GB); William MITCHELL, Chandler's Ford (GB); Pawel MISKIEWICZ, Neu-Isenburg (DE); Toshiaki NONAKA, Machida-City (JP)

(73) Assignee: Merck Patent GmbH, Darmstadt (DE)

(21) Appl. No.: 17/436,746

(22) PCT Filed: Mar. 6, 2020
(86) PCT No.: PCT/EP2020/055952

§ 371 Date: Sep. 7, 2021

(30) Foreign Application Priority Data
Mar. 8, 2019 (EP) 19161650.7

(51) Int. Cl. C08G 77/04; C08G 77/26; C09D 183/08; G03F 7/075; H01L 21/02

(52) U.S. Cl. CPC C08G 77/045; C08G 77/26; H01L 21/02118; G03F 7/0757; C09D 183/08

(57) ABSTRACT

The present invention relates to novel siloxane oligomer and polymers and crosslinkable compositions, which may be used for the preparation of dielectric materials having excellent barrier, passivation and/or planarization properties. There is also provided a monomer composition from which the siloxane oligomers or polymers may be obtained and a method for preparing said siloxane oligomers or polymers. Beyond that, the present invention relates to a manufacturing method for preparing a microelectronic structure, wherein a crosslinkable composition is applied to a surface of a substrate and then cured, and to an electronic device comprising a microelectronic structure which is obtained by said manufacturing method.

### TECHNICAL FIELD OF THE INVENTION

The present invention relates to novel siloxane oligomers and polymers and crosslinkable compositions, which may be used for the preparation of dielectric materials having excellent barrier, passivation and/or planarization properties. Said dielectric materials may be used for various applications in electronics industry, such as e.g. for electronic packaging or preparation of field effect transistors (FETs) or thin film transistors (TFTs). The dielectric material may form barrier coatings, passivation layers, planarization layers or combined passivation and planarization layers on conducting or semi-conducting structures. Moreover, the materials may be used for preparing substrates for printed circuit boards.

The siloxane oligomers or polymers of the present invention are co-oligomers or copolymers which are obtained from a specific monomer composition comprising at least two different siloxane monomers. The oligomers and polymers are photostructurable and may be used for the preparation of passivation layers or barrier coatings in packaged electronic devices or for the passivation and optional planarization of semiconductor structures in FET or TFT devices. Here, a cured dielectric material is obtained from the siloxane polymers showing excellent film forming capability, excellent thermal properties, excellent mechanical properties as well as an easy handling and processing from conventional solvents. In addition, the material is characterized by a low dielectric constant and a low coefficient of thermal expansion (CTE). Due to a favorable and well-balanced relationship between stiffness and elasticity of the material, thermal stress which may occur during device operation can be easily compensated.

There is further provided a method for preparing said siloxane oligomers or polymers and a crosslinkable oligomer or polymer composition comprising said siloxane oligomers or polymers. Beyond that, the present invention relates to a manufacturing method for preparing a microelectronic structure, wherein a crosslinkable oligomer or polymer composition is applied to a surface of a substrate and then cured, and to an electronic device comprising a microelectronic structure which is obtained or obtainable by said manufacturing method.

The manufacturing method of the present invention allows a cost-effective and reliable manufacturing of microelectronic devices where the number of defective products caused by mechanical deformation (warping) due to undesirable thermal expansion is significantly reduced. Polymerization can occur at lower temperatures and thus leading to lower thermal stress during manufacturing, which reduces the waste of defective microelectronic devices, thereby allowing a resource-efficient and sustainable production.

### BACKGROUND OF THE INVENTION

Various materials have been described for the preparation of dielectric coatings or layers in electronics industry. For example, US 2012/0056249 A1 relates to polycycloolefins which are based on norbornene-type polymers and which are used for the preparation of dielectric interlayers applied to fluoropolymer layers in electronic devices.

WO 2017/144148 A1 provides a positive type photosensitive siloxane composition capable of forming cured films, such as a planarization film for a TFT substrate or an interlayer insulating film. The positive type photosensitive siloxane composition comprises (I) a polysiloxane having a substituted or unsubstituted phenyl group, (II) a diazonaphthoquinone derivative, (Ill) a hydrate or solvate of a photo base-generator, and (IV) a solvent.

US 2013/0099228 A1 relates to a passivation layer solution composition containing an organic siloxane resin represented by

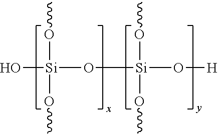

wherein R is at least one substituent elected from a saturated hydrocarbon or an unsaturated hydrocarbon having from 1 to about 25 carbon atoms, and x and y may each independently be from 1 to about 200, and wherein each wavy line indicates a bond to an H atom or to an x siloxane unit or a y siloxane unit, or a bond to an x siloxane unit or a y siloxane unit of another siloxane chain comprising x siloxane units or y siloxane units or a combination thereof. The passivation layer solution composition is used for preparing passivation layers on oxide semiconductors in thin film transistor (TFT) array panels.

Polyfunctional polyorganosiloxanes are described in DE 4014882 A1, which can be used for the production of polymers with liquid crystalline side chains or for the preparation of photosensitive resists or photo-crosslinkable coatings.

Furthermore, US 2007/0205399 A1 relates to functionalized cyclic siloxanes, which are useful as thermosetting adhesive resins for the electronic packaging industry, and US 2011/0319582 A1 relates to curable compositions comprising a reaction product obtained by reacting an alkoxysilane compound and inorganic oxide microparticles in the presence of water and an organic solvent.

As it is apparent from the above discussion, organopolysiloxanes are a very interesting class of compounds due to their thermal stability and mechanical hardness and they are used for a variety of different applications such as e.g. for the formation of cured films having high heat resistance, transparency and resolution. Organopolysiloxanes with methyl and/or phenyl side groups are used as dielectric materials in the electronic industry (mainly front-end of line (FEOL)), where thermally stable materials are needed. These materials have to withstand temperatures of up to 600° C. However, the known materials are too rigid and brittle for the use in back-end of line (BEOL) applications, namely redistribution, stress buffer, or passivation layer where temperature requirements are somewhat smaller (250-300° C.), but mechanical properties are becoming much more important, such as elongation and thermal expansion.

Flexible material systems are required to prevent device cracking or delamination of coatings. Usually, such material systems are modified and adapted to specific application requirements by complex blending concepts of currently more than ten different compounds in order to adjust the desired mechanical, thermal and/or electrical properties. Advantageously, organopolysiloxane-type polymers are tailorable to overcome possible drawbacks such as poor adhesion, poor elongation or high thermal expansion/shrinkage and may prevent complex multi-component solutions.

Hence, there is a continuous need to develop new compounds which may be used as dielectric materials or barrier coating materials for various applications in electronics industry, such as e.g. for packaging of microelectronic devices or for preparation of field effect transistors (FETs) or thin film transistors (TFTs).

### OBJECT OF THE INVENTION

It is an object of the present invention to overcome the deficiencies and drawbacks in the prior art and to provide new compounds which allow the preparation of dielectric materials having excellent barrier, passivation and/or planarization properties, which can be used for various applications in electronics industry. Preferred applications are, e.g. electronic packaging or preparation of FET or TFT devices. The dielectric material may form barrier coatings, passivation layers, planarization layers or combined passivation and planarization layers on conducting or semiconducting structures.

Moreover, it is an object to provide new dielectric materials which show excellent film forming capabilities, excellent thermal properties, such as e.g. a low coefficient of thermal expansion, and excellent mechanical properties, such as e.g. excellent flexibility, when used for the formation of passivation layers in packaged electronic devices. It is a further object to provide new dielectric materials which allow an easy handling and processing from conventional solvents.

Moreover, it is an object to provide new compounds which are photostructurable and which are particularly suitable for various applications in electronics industry, such as e.g. for preparing passivation layers or barrier coatings on conducting or semiconducting structures in packaged electronic devices or for passivating and/or planarizing of semiconductor layers in FETs or TFTs.

More specifically, it is an object of the present invention to provide new crosslinkable compositions which allow the preparation of dielectric materials for structuring redistribution layers (RDLs) in packaged microelectronic devices, prepared by wafer-level packaging or panel-level packaging, or for passivating and optional planarizing semiconductor layers in FET or TFT devices.

Hence, a first aspect of the present invention resides in the provision of a monomer composition for the preparation of an oligomer or polymer which may be used for the above-mentioned purposes.

A second aspect of the present invention resides in the provision of a method for preparing said oligomer or polymer.

A third aspect of the present invention resides in the provision of said oligomer or polymer.

A fourth aspect of the present invention resides in the provision of a crosslinkable oligomer or polymer composition comprising said oligomer or polymer.

A fifth aspect of the present invention resides in the provision of a manufacturing method for a microelectronic structure.

A sixth aspect of the present invention resides in the provision of an electronic device comprising said microelectronic structure.

### SUMMARY OF THE INVENTION

The present inventors have surprisingly found that the above objects are achieved by the provision of a monomer composition for the preparation of a siloxane oligomer or polymer, wherein the monomer composition comprises:

(a) a first siloxane monomer; and
(b) a second siloxane monomer;
wherein the first siloxane monomer comprises a substituted or unsubstituted maleimide group.

Said monomer composition is used for the preparation of photostructurable siloxane oligomer or polymers which may form crosslinked dielectric materials exhibiting excellent film forming capabilities, excellent thermal properties, such as e.g. a low coefficient of thermal expansion, and excellent mechanical properties, such as e.g. excellent flexibility, when used for the formation of passivation layers in packaged electronic devices.

Hence, the present invention further provides a method for preparing a siloxane oligomer or polymer, wherein the method comprises the following steps:

(i) providing a monomer composition according to the present invention; and
(ii) reacting the monomer composition provided in step (i) to obtain a siloxane oligomer or polymer.

Moreover, a siloxane oligomer or polymer is provided, which is obtainable or obtained by the above-mentioned method for preparing a siloxane oligomer or polymer.

Furthermore, a siloxane oligomer or polymer is provided which comprises or consists of a first repeating unit, wherein the first repeating unit is derived from a first siloxane monomer comprising a substituted or unsubstituted maleimide group.

Beyond that, a crosslinkable oligomer or polymer composition is provided which comprises one or more of the above-mentioned siloxane oligomer(s) or polymer(s).

Finally, a method for manufacturing a microelectronic structure, preferably a packaged microelectronic structure, a FET structure or a TFT structure, is provided, comprising the following steps:

(1) applying a crosslinkable oligomer or polymer composition according to the present invention to a surface of a substrate, preferably to a surface of a conducting or semiconducting substrate; and
(2) curing said crosslinkable oligomer or polymer composition to form a layer which passivates and optionally planarizes the surface of the substrate.

There is also provided an electronic device, preferably a packaged microelectronic device, a FET array panel or a TFT array panel, comprising a microelectronic structure, obtainable or obtained by the method for manufacturing according to the present invention.

Preferred embodiments of the present invention are described hereinafter and in the dependent claims.

### BRIEF DESCRIPTION OF THE FIGURES

FIG. 1: Cross section of substrate for capacitance measurement.

FIG. 2: Top view of substrate for capacitance measurements showing points at which film thickness was measured.

### DETAILED DESCRIPTION

### Electronic Packaging

As solid-state transistors started to replace vacuum-tube technology, it became possible for electronic components, such as resistors, capacitors, and diodes, to be mounted directly by their leads into printed circuit boards of cards, thus establishing a fundamental building block or level of packaging that is still in use. Complex electronic functions often require more individual components than can be interconnected on a single printed circuit card. Multilayer card capability was accompanied by development of three-dimensional packaging of daughter cards onto multilayer mother boards. Integrated circuitry allows many of the discrete circuit elements such as resistors and diodes to be embedded into individual, relatively small components known as integrated circuit chips or dies. In spite of incredible circuit integration, however, more than one packaging level is typically required, in part because of the technology of integrated circuits itself. Integrated circuit chips are quite fragile, with extremely small terminals. First-level packaging achieves the major functions of mechanically protecting, cooling, and providing capability for electrical connections to the delicate integrated circuit. At least one additional packaging level, such as a printed circuit card, is utilized, as some components (high-power resistors, mechanical switches, capacitors) are not readily integrated onto a chip. For very complex applications, such as mainframe computers, a hierarchy of multiple packaging levels is required.

As a consequence of Moore's law, advanced electronic packaging strategies are playing an increasingly important role in the development of more powerful electronic products. In other words, as the demand for smaller, faster, and more functional mobile and portable electronic devices increases, the demand for improved cost-effective packaging technologies is also increasing. A wide variety of advanced packaging technologies exist to meet the requirements of today's semiconductor industry. The leading Advanced Packaging technologies—wafer-level packaging (WLP), fan-out wafer level packaging (FOWLP), 2.5D interposers, chip-on-chip stacking, package-on-package stacking, embedded IC—all require structuring of thin substrates, redistribution layers and other components like high resolution interconnects. The end consumer market presents constant push for lower prices and higher functionality on ever smaller and thinner devices. This drives the need for the next generation packaging with finer features and improved reliability at a competitive manufacturing cost.

Wafer-level packaging (WLP) is the technology of packaging an integrated circuit while still part of the wafer, in contrast to the more conventional chip scale packaging method, where the wafer is sliced into individual circuits (dices) and then packaged. WLP offers several major advantages compared to chip scale package technologies and it is essentially a true chip-scale package (CSP) technology, since the resulting package is practically of the same size as the die. Wafer-level packaging allows integration of wafer fab, packaging, test, and burn-in at wafer-level in order to streamline the manufacturing process undergone by a device from silicon start to customer shipment. Major application areas of WLP are smartphones and wearables due to their size constraints. Functions provided WLPs in smartphones or wearables include: compass, sensors, power management, wireless etc. Wafer-level chip scale packaging (WL-CSP) is one of the smallest packages currently available on the market. WLP can be categorized into fan-in and fan-out WLP. Both of them use a redistribution technology to form the connections between chips and solder balls.

Fan-out wafer-level packaging (FOWLP) is one of the latest packaging trends in microelectronics: FOWLP has a high miniaturization potential both in the package volume as well as in the packaging thickness. Technological basis of FOWLP is a reconfigured, painted wafer with embedded chips and a thin film rewiring layer, which together form a surface-mounted device (SMD)-compatible package. The main advantages of the FOWLP are a very thin, because substrateless package, the low thermal resistance, good high-frequency properties due to short and planar electrical connections together with a bumpless chip connection instead of e.g. wire bonds or solder contacts.

With current materials, WLP processes are limited to medium chip size applications. The reasons for this restriction are mainly due to the current material selection, which shows a thermal mismatch with the silicon die and therefore can reduce the performance and generate stress on the dies. New materials with better mechanical properties (in particular, a coefficient of thermal expansion (CTE) closer to the CTE of silicon) are in high demand. Currently, redistribution layers (RDLs) are made from copper layers, which are electroplated on polymer passivation layers such as polyimides (PI), butylcyclobutanes (BCB), or polybenzoxazoles (PBO). Low curing temperatures in addition to photopaternability are two further important requirements for such materials.

### Thin Film Transistors (TFTs)

Thin film transistor (TFT) array panel are typically used as circuit boards for independently driving pixels in liquid crystal, electrophoretic particle/liquid, organic electro-luminescent (EL) display devices, quantum dot electro-luminescent and light emitting diodes. A TFT array panel includes a scanning line or a gate line transmitting a scanning signal, an image signal line or a data line transmitting an image signal, a thin film transistor connected to the gate line and the data line, and a pixel electrode connected to the thin film transistor. A TFT includes a gate electrode that is a portion of the gate wire, a semiconductor layer forming a channel, a source electrode that is a portion of the data wire, and a drain electrode. The TFT is a switching element controlling an image signal transmitted to the pixel electrode through the data wire according to the scanning signal transmitted through the gate line.

For the deposition of silicon nitride/silicon oxide layers onto a silicon or oxide semiconductor substrate, two methods are currently in use:
Low pressure chemical vapor deposition (LPCVD) technology, which works at rather high temperature and is performed either in a vertical or in a horizontal tube furnace; or
Plasma-enhanced chemical vapor deposition (PECVD) technology, which works at rather low temperature and under vacuum conditions.

It is experienced that SiNx films made by LPCVD with thicknesses of 200 nm and larger tend to crack easily under pressure or temperature change. The process temperature is too high to apply for glass substrate and hydrogenated amorphous silicon or oxide semiconductors. SiNx films made by PECVD have less tensile stress, but which still causes glass substrate curling with elevated glass substrate size. Also it has worse electrical properties. The plasma can also damage thin film semiconductor, especially oxide semiconductors to degrade TFT performance.

Photostructuring of SiN layers requires many steps including photoresist coating, photo patterning, SiNx etching, photoresist stripping, cleaning, etc. These procedures are time and cost consuming. Hence, new types of materials are required for passivating semiconductor layers in TFTs forming part of TFT array panels.

### Definitions

The term “polymer” includes, but is not limited to, homopolymers, copolymers, for example, block, random, and alternating copolymers, terpolymers, quaterpolymers, etc., and blends and modifications thereof. Furthermore, unless otherwise specifically limited, the term “polymer” shall include all possible configurational isomers of the material. These configurations include, but are not limited to isotactic, syndiotactic, and atactic symmetries. A polymer is a molecule of high relative molecular mass, the structure of which essentially comprises the multiple repetition of units (i.e. repeating units) derived, actually or conceptually, from molecules of low relative mass (i.e. monomers). In the context of the present invention polymers are composed of more than 60 monomers.

The term “oligomer” is a molecular complex that consists of a few monomer units, in contrast to a polymer, where the number of monomers is, in principle, unlimited. Dimers, trimers and tetramers are, for instance, oligomers composed of two, three and four monomers, respectively. In the context of the present invention oligomers may be composed of up to 60 monomers.

The term “monomer” as used herein, refers to a polymerizable compound which can undergo polymerization thereby contributing constitutional units (repeating units) to the essential structure of a polymer or an oligomer. Polymerizable compounds are functionalized compounds having one or more polymerizable groups. Large numbers of monomers combine in polymerization reactions to form polymers. Monomers with one polymerizable group are also referred to as “monofunctional” or “monoreactive” compounds, compounds with two polymerizable groups as “bifunctional” or “direactive” compounds, and compounds with more than two polymerizable groups as “multifunctional” or “multireactive” compounds. Compounds without a polymerizable group are also referred to as “non-functional” or “non-reactive” compounds.

The term “homopolymer” as used herein, stands for a polymer derived from one species of (real, implicit or hypothetical) monomer.

The term “copolymer” as used herein, generally means any polymer derived from more than one species of monomer, wherein the polymer contains more than one species of corresponding repeating unit. In one embodiment the copolymer is the reaction product of two or more species of monomer and thus comprises two or more species of corresponding repeating unit. It is preferred that the copolymer comprises two, three, four, five or six species of repeating unit. Copolymers that are obtained by copolymerization of three monomer species can also be referred to as terpolymers. Copolymers that are obtained by copolymerization of four monomer species can also be referred to as quaterpolymers. Copolymers may be present as block, random, and/or alternating copolymers.

The term “block copolymer” as used herein, stands for a copolymer, wherein adjacent blocks are constitutionally different, i.e. adjacent blocks comprise repeating units derived from different species of monomer or from the same species of monomer but with a different composition or sequence distribution of repeating units.

Further, the term “random copolymer” as used herein, refers to a polymer formed of macromolecules in which the probability of finding a given repeating unit at any given site in the chain is independent of the nature of the adjacent repeating units. Usually, in a random copolymer, the sequence distribution of repeating units follows Bernoullian statistics.

The term “alternating copolymer” as used herein, stands for a copolymer consisting of macromolecules comprising two species of repeating units in alternating sequence.

“Siloxanes” are chemical compounds with the general formula R₃Si[OSiR₂]ₙOSiR₃ or (RSi)ₙO_{3n/2}, where R can be hydrogen atoms or organic groups and n is an integer 1. In contrast to silanes, the silicon atoms of siloxanes are not directly linked to one another, but via an intermediate oxygen atom: Si—O—Si. Depending on the chain length, siloxanes may occur as linear or branched or cubic or ladder shaped or random oligomeric or polymer siloxanes (i.e. oligosiloxanes or polysiloxanes). Siloxanes, where at least one substituent R is an organic group, are called organosiloxanes.

“Halogen” as used herein refers to an element which belongs to group 17 of the Periodic Table. Group 17 of the Periodic Table comprises the chemically relevant elements fluorine (F), chlorine (Cl), bromine (Br), iodine (I) and astatine (At).

As explained above, “electronic packaging” is a major discipline within the field of electronic engineering, and includes a wide variety of technologies. It refers to inserting discrete components, integrated circuits, and MSI (medium-scale integration) and LSI (large-scale integration) chips (usually attached to a lead frame by beam leads) into plates through hole on multilayer circuit boards (also called cards), where they are soldered in place. Packaging of an electronic system must consider protection from mechanical damage, cooling, radio frequency noise emission, protection from electrostatic discharge maintenance, operator convenience, and cost.

The term “microelectronic device” as used herein, refers to electronic devices of very small electronic designs and components. Usually, but not always, this means micrometer-scale or smaller. These devices typically contain one or more microelectronic components which are made from semiconductor materials and interconnected in a packaged structure to form the microelectronic device. Many electronic components of normal electronic design are available in a microelectronic equivalent. These include transistors, capacitors, inductors, resistors, diodes and naturally insulators and conductors can all be found in microelectronic devices. Unique wiring techniques such as wire bonding are also often used in microelectronics because of the unusually small size of the components, leads and pads.

The term “field effect transistor” or “FET” as used herein, refers to a transistor that uses an electric filed to control the electrical behavior of the device. FETs are also known as unipolar transistors since they involve single-carrier-type operation. Many different implementations of field effect transistors exist. Field effect transistors generally display very high input impedance at low frequencies. The conductivity between the drain and source terminals is controlled by an electric field in the device, which is generated by the voltage difference between the body and the gate of the device.

The term “thin film transistor” or “TFT” as used herein, refers to a specific kind of transistor made by depositing thin films of an active semiconductor layer as well as a dielectric layer and metallic contacts over a supporting (but non-conducting) substrate. A common substrate is glass, because the primary application of TFTs is in liquid-crystal displays (LCDs). This differs from the conventional transistor, where the semiconductor material typically is the substrate such as a silicon wafer. TFTs may be used to form a TFT array panel for a liquid crystal display (LCD) device.

### Preferred Embodiments

### Monomer Composition

In a first aspect, the present invention relates to a monomer composition for the preparation of a siloxane oligomer or polymer, comprising:

(a) a first siloxane monomer; and
(b) a second siloxane monomer;
wherein the first siloxane monomer comprises a substituted or unsubstituted maleimide group.

A maleimide group is a functional group represented by the following structure:

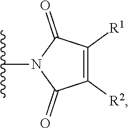

wherein R¹ and R² are the same or different from each other and each independently denotes H or a substituent. If both R¹ and R² are H, the maleimide group is an unsubstituted maleimide group. If at least one of R¹ and R² is a substituent different from H, the maleimide group is a substituted maleimide group.

The synthesis of maleimide-functionalized trialkoxysilanes is described in CN 104447849 A.

### First Siloxane Monomer

In a preferred embodiment, the first siloxane monomer (a), comprised in the monomer composition according to the present invention, is represented by Formula (1):

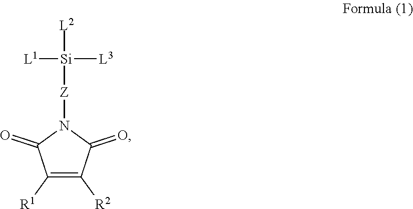

wherein:
L¹, L² and L³ are the same or different from each other and each independently is selected from R, OR, and halogen, wherein at least one of
L¹, L² and L³ is OR or halogen;
R is selected from the group consisting of H, straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C═C—, and wherein one or more H atoms are optionally replaced by F;
R¹ and R² are the same or different from each other and each independently is selected from H, alkyl having 1 to 20 carbon atoms, cycloalkyl having 3 to 20 carbon atoms and aryl having 6 to 20 carbon atoms, wherein one or more H atoms are optionally replaced by F, or R¹ and R² together form a mono- or polycyclic organic ring system, wherein one or more H atoms are optionally replaced by F;
Z denotes a straight-chain alkylene group having 1 to 20 carbon atoms, a branched-chain alkylene group having 3 to 20 carbon atoms or a cyclic alkylene group having 3 to 20 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C═C—, and in which one or more H atoms are optionally replaced by F;
Y¹ and Y² are the same or different from each other and each independently is selected from H, F, Cl and CN;
R⁰ and R⁰⁰ are the same or different from each other and each independently is selected from H, straight-chain alkyl having 1 to 20 carbon atoms and branched-chain alkyl having 3 to 20 carbon atoms, which are optionally fluorinated; and
wherein the second siloxane monomer is different from the first siloxane monomer.

It is preferred that L¹, L² and L³ are the same or different from each other and each independently is selected from R, OR, F, Cl, Br and I, wherein at least one of L¹, L² and L³ is OR, F, Cl, Br or I.

It is more preferred that one of the conditions (1) or (2) applies:

L¹=L²=L³=OR; or (1)

L¹=L²=R, and L³=Cl. (2)

In a preferred embodiment, R is selected from the group consisting of H, straight chain alkyl having 1 to 20, preferably 1 to 12, carbon atoms, branched-chain alkyl having 3 to 20, preferably 3 to 12, carbon atoms, cyclic alkyl having 3 to 20, preferably 3 to 12, carbon atoms, and aryl having 6 to 14 carbon atoms, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C═C—, and wherein one or more H atoms are optionally replaced by F.

In a more preferred embodiment, R is selected from the group consisting of H, straight chain alkyl having 1 to 12 carbon atoms, branched-chain alkyl having 3 to 12 carbon atoms, cyclic alkyl having 3 to 12 carbon atoms, and aryl having 6 to 14 carbon atoms.

In a most preferred embodiment, R is selected from the group consisting of H, —CH₃, —CH₂CH₃, —CH₂CH₂CH₃, —CH(CH₃)₂, —C₆H₁₁, and -Ph.

In a preferred embodiment, R¹ and R² are the same or different from each other and each independently is selected from H, alkyl having 1 to 12 carbon atoms, cycloalkyl having 3 to 12 carbon atoms and aryl having 6 to 14 carbon atoms, wherein one or more H atoms are optionally replaced by F, or R¹ and R² together form a mono- or polycyclic aliphatic ring system, a mono- or polycyclic aromatic ring system or a polycyclic aliphatic and aromatic ring system, wherein one or more H atoms are optionally replaced by F.

Preferred mono- or polycyclic aliphatic ring systems have 3 to 20, preferably 5 to 12, ring carbon atoms. Preferred mono- or polycyclic aromatic ring systems have 5 to 20, preferably 6 to 12, ring carbon atoms. Preferred polycyclic aliphatic and aromatic ring system have 6 to 30, preferably 10 to 20, ring carbon atoms.

In a more preferred embodiment, R¹ and R² are the same or different from each and are selected from H, —CH₃, —CF₃, —CH₂CH₃, —CF₂CF₃, —CH₂CH₂CH₃, —CH(CH₃)₂, or -Ph.

In an even more preferred embodiment, R¹ and R² are the same and selected from —CH₃, —CF₃, —CH₂CH₃, —CF₂CF₃ or -Ph.

In a most preferred embodiment, R¹ and R² are —CH₃.

In a preferred embodiment, Z denotes a straight-chain alkylene group having 1 to 12 carbon atoms, a branched-chain alkylene group having 3 to 12 carbon atoms or a cyclic alkylene group having 3 to 12 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡O—, and in which one or more H atoms are optionally replaced by F.

In a more preferred embodiment, Z denotes a straight-chain alkylene group having 1 to 12 carbon atoms, which is selected from —(CH₂)—, —(CH₂)₂—, —(CH₂)₃—, —(CH₂)₄—, —(CH₂)₅—, —(CH₂)₆—, —(CH₂)₇—, —(CH₂)₈—, —(CH₂)₉—, —(CH₂)₁₉—, —(CH₂)₁₁—, and —(CH₂)₁₂—.

In a preferred embodiment, R⁰ and R⁰⁰ are the same or different from each other and each independently is selected from H, straight-chain alkyl having 1 to 12 carbon atoms and branched-chain alkyl having 3 to 12 carbon atoms, which are optionally fluorinated.

In a more preferred embodiment, R⁰ and R⁰⁰ are the same or different from each other and each independently is selected from H, —CH₃, —CF₃, —CH₂CH₃ and —CF₂CF₃.

Particularly preferred first siloxane monomers are represented by Formula (2):

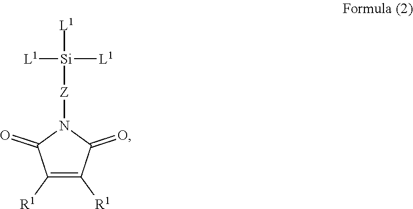

wherein:
L¹=—OCH₃, —OCF₃, —OCH₂CH₃, —OCF₂CF₃, —OCH₂CH₂CH₃, —OCH(CH₃)₂, —OC₆H₁₁, or -Ph;
Z═—(CH₂)ₙ—, wherein n=1 to 10; and
R¹═H, —CH₃, —CF₃, —CH₂CH₃, —CF₂CF₃, or -Ph.

In a most preferred embodiment, the first siloxane monomer is represented by Formula (3):

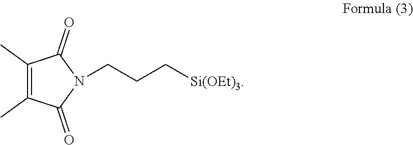

### Second Siloxane Monomer

In a preferred embodiment, the second siloxane monomer, comprised in the monomer composition according to the present invention, is represented by one of the following Structures S1 to S5:

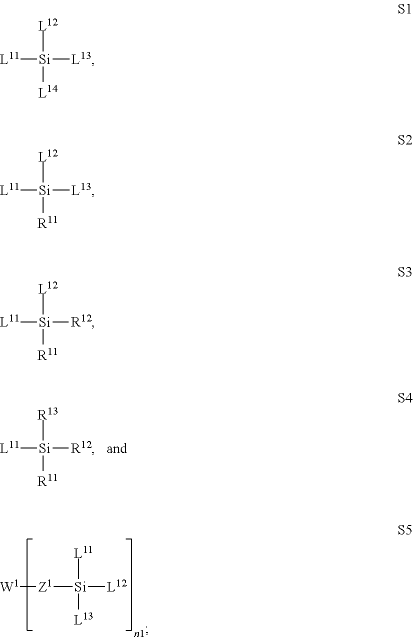

wherein:
L¹¹, L¹², L¹³, and L¹⁴ are the same or different from each other and each independently is selected from OR′ and halogen;
R′ is selected from the group consisting of straight-chain alkyl having 1 to 30 carbon atoms, branched-chain alkyl having 3 to 30 carbon atoms, cyclic alkyl having 3 to 30 carbon atoms, and aryl having 6 to 20, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡O—, and wherein one or more H atoms are optionally replaced by F;
R¹¹, R¹² and R¹³ are the same or different from each other and each independently is selected from the group consisting of H, straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, which optionally contain one or more functional groups selected from —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CR⁰═CR⁰⁰₂, —CY¹═CY²—, and —C≡O—, and
wherein one or more H atoms are optionally replaced by F;
Z¹ denotes a straight-chain alkylene group having 1 to 20 carbon atoms, a branched-chain alkylene group having 3 to 20 carbon atoms or a cyclic alkylene group having 3 to 20 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡O—, and in which one or more H atoms are optionally replaced by F;
W¹ denotes a divalent, trivalent or tetravalent organic moiety;
R⁰, R⁰⁰, Y¹, and Y² are defined as shown above; and
n1=2, 3 or 4.

It is preferred that L¹¹, L¹², L¹³, and L¹⁴ are the same or different from each other and each independently is selected from OR′, F, Cl, Br and I.

It is more preferred that L¹¹, L¹², L¹³, and L¹⁴ are the same or different from each other and each independently is selected from OR′.

In a preferred embodiment, R′ is selected from the group consisting of straight chain alkyl having 1 to 20, preferably 1 to 12, carbon atoms, branched-chain alkyl having 3 to 20, preferably 3 to 12, carbon atoms, cyclic alkyl having 3 to 20, preferably 3 to 12, carbon atoms, and aryl having 6 to 14 carbon atoms, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡O—, and wherein one or more H atoms are optionally replaced by F.

In a more preferred embodiment, R′ is selected from the group consisting of straight chain alkyl having 1 to 12 carbon atoms, branched-chain alkyl having 3 to 12 carbon atoms, cyclic alkyl having 3 to 12 carbon atoms, and aryl having 6 to 14 carbon atoms.

In a particularly preferred embodiment, R′ is selected from the group consisting of —CH₃, —CF₃, —C₂H₅, —C₂F₅, —C₃H₇, —C₃F₇, —C₄H₉, —C₄F₉, —C₅H₁₁, —C₅H₄F₇, —C₆H₁₃, —C₆H₄F₉, —C₇H₁₅, —C₇H₄F₁₁, —C₈H₁₇, —C₈H₄F₁₃, —CH═CH₂, —C(CH₃)═CH₂, —C₆H₅, and —C₆F₅.

In a most preferred embodiment, R′ is selected from —CH₃, or —C₂H₅.

In a preferred embodiment, R¹¹, R¹² and R¹³ are the same or different from each other and each independently is selected from the group consisting of H, straight-chain alkyl having 1 to 20, preferably 1 to 12, carbon atoms, branched-chain alkyl having 3 to 20, preferably 3 to 12, carbon atoms, cyclic alkyl having 3 to 20, preferably 3 to 12, carbon atoms, and aryl having 6 to 14 carbon atoms, which optionally contain one or more functional groups selected from —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CR⁰═CR⁰⁰₂, —CY¹═CY²—, and —C≡O—, and wherein one or more H atoms are optionally replaced by F.

In a more preferred embodiment, R¹¹, R¹² and R¹³ are selected from the group consisting of H, straight-chain alkyl having 1 to 12 carbon atoms, branched-chain alkyl having 3 to 12 carbon atoms, cyclic alkyl having 3 to 12 carbon atoms, and aryl having 6 to 14 carbon atoms, which optionally contain one or more functional groups selected from —C(═O)—, —C(═O)—O—, —O—C(═O)—, —CR⁰═CR⁰⁰—, —CR⁰═CR⁰⁰₂, and —CY¹═CY²—, and wherein one or more H atoms are optionally replaced by F.

In a particularly preferred embodiment R¹¹, R¹² and R¹³ are selected from the group consisting of —CH₃, —CF₃, —C₂H₅, —C₂F₅, —C₃H₇, —C₃F₇, —C₄H₉, —C₄F₉, —C₅H₁₁, —C₅H₄F₇, —C₆H₁₃, —C₆H₄F₉, —C₇H₁₅, —C₇H₄F₁₁, —C₈H₁₇, —C₈H₄F₁₃, —CH═CH₂, —C(CH₃)═CH₂, —C₃H₆—O—C(═O)—CH═CH₂, —C₃H₆—O—C(═O)—C(CH₃)═CH₂, —C₆H₅, and —C₆F₅.

In a most preferred embodiment, R¹¹, R¹² and R¹³ are selected from —CH₃, or —C₂H₅.

In a preferred embodiment, Z¹ denotes a straight-chain alkylene group having 1 to 12 carbon atoms, a branched-chain alkylene group having 3 to 12 carbon atoms or a cyclic alkylene group having 3 to 12 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡O—, and in which one or more H atoms are optionally replaced by F.

In a more preferred embodiment, Z¹ denotes a straight-chain alkylene group having 1 to 12 carbon atoms, which is selected from —(CH₂)—, —(CH₂)₂—, —(CH₂)₃—, —(CH₂)₄—, —(CH₂)₅—, —(CH₂)₆—, —(CH₂)₇—, —(CH₂)₈—, —(CH₂)₉—, —(CH₂)₁₀—, —(CH₂)₁₁—, and —(CH₂)₁₂—.

In a preferred embodiment, W¹ is represented by one of the following Structures W1 to W4:

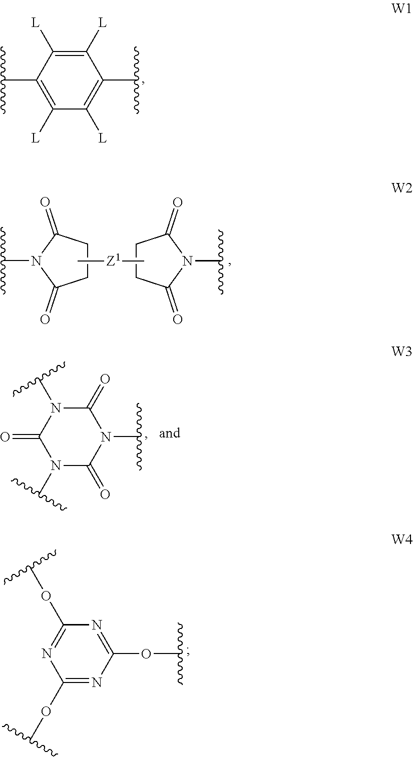

wherein:
L is selected from H, —F, —Cl, —NO₂, —CN, —NC, —NCO, —NCS, —OCN, —SCN, —OH, —R⁰, —OR⁰, —SR⁰, —C(═O)R⁰, —C(═O)—OR⁰, —O—C(═O)—R⁰, —NH₂, —NHR⁰, —NR⁰R⁰⁰, —C(═O)NHR⁰, —C(═O)NR⁰R⁰⁰, —SO₃R⁰, —SO₂R⁰, an alkyl group with 1 to 20 carbon, preferably 1 to 12, atoms, or an aryl group with 6 to 20, preferably 6 to 14, carbon atoms, which may optionally be substituted by —F, —Cl, —NO₂, —CN, —NC, —NCO, —NCS, —OCN, —SCN, —OH, —R⁰, —OR⁰, —SR⁰, —C(═O)—R⁰, —C(═O)—OR⁰, —O—C(═O)—R⁰, —NH₂, —NHR⁰, NR⁰R⁰⁰, —O—C(═O)—OR⁰, —C(═O)—NHR⁰, or —C(═O)—NR⁰R⁰⁰.

For R⁰ and R⁰⁰, the above-mentioned definitions apply, correspondingly.

In a preferred embodiment, L is selected from H, —F, —Cl, —NO₂, —OCH₃, —CH₃, CF₃, —CH₂CH₃, —CH₂CH₂CH₃, and —CH(CH₃)₂, -Ph, and C₆F₅.

Preferred second siloxane monomers are represented by one of the following structures:

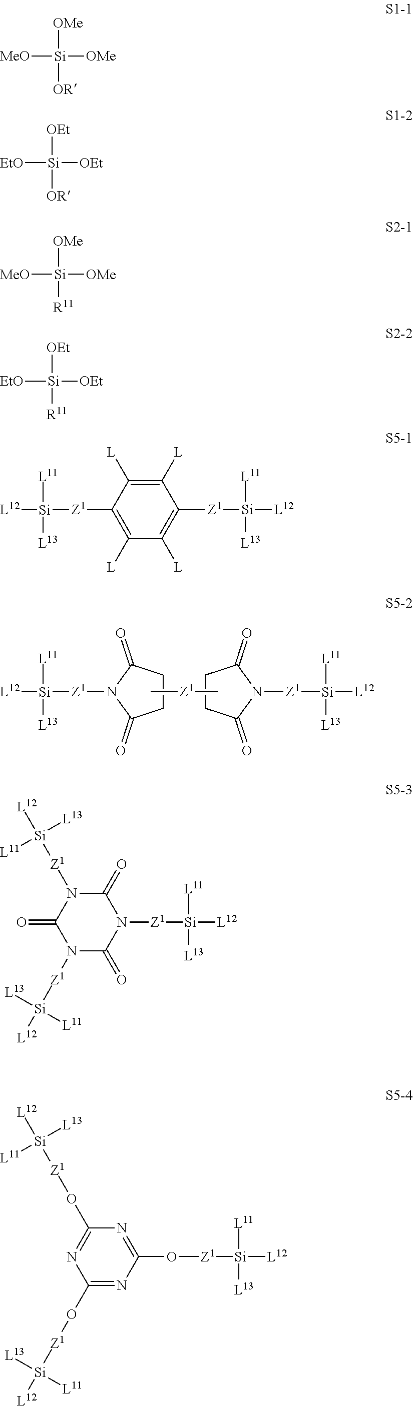

wherein:
R¹¹ has one of the meanings as defined above;
L¹¹, L¹², and L¹³ are the same or different from each other and each independently is selected from OR′ and halogen; and
R′, Z¹ and L have one of the meanings as defined as above.

More preferred second siloxane monomers are represented by one of the following structures:

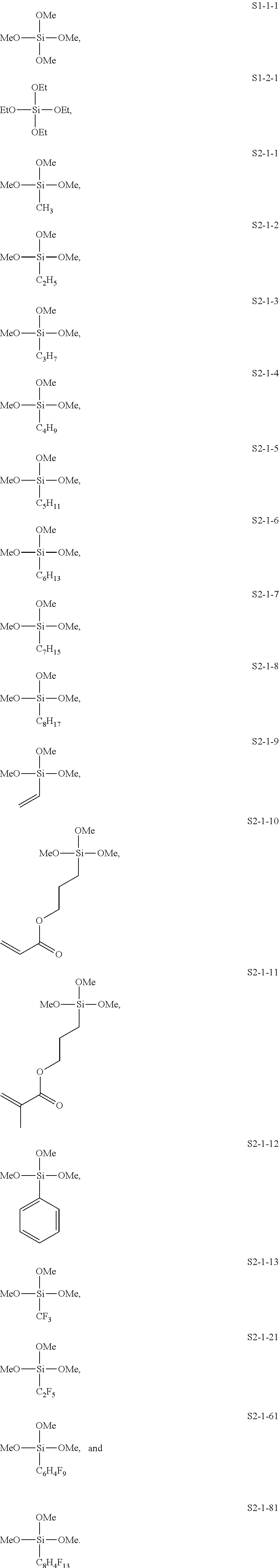

### Third Siloxane Monomer

In a preferred embodiment, the monomer composition according to the present invention further comprises:

(c) a third siloxane monomer;
wherein the third siloxane monomer is different from the first siloxane monomer and the second siloxane monomer.

Preferably, the third siloxane monomer is represented by one of the following Structures T1 to T5:

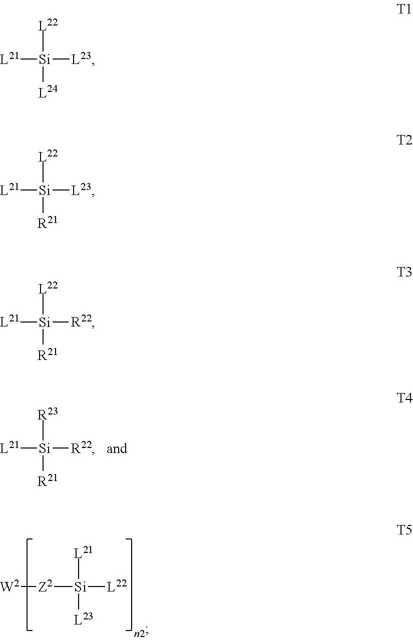

wherein:
L²¹, L²², L²³, and L²⁴ are the same or different from each other and each independently is selected from OR″ and halogen;
R″ is selected from the group consisting of straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡O—, and wherein one or more H atoms are optionally replaced by F;
R²¹, R²² and R²³ are the same or different from each other and each independently is selected from the group consisting of H, straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, which optionally contain one or more functional groups selected from —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CR⁰═CR⁰⁰₂, —CY¹═CY²—, and —C≡O—, and
wherein one or more H atoms are optionally replaced by F;
Z² denotes a straight-chain alkylene group having 1 to 20 carbon atoms, a branched-chain alkylene group having 3 to 20 carbon atoms or a cyclic alkylene group having 3 to 20 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡O—, and in which one or more H atoms are optionally replaced by F;
W² denotes a divalent, trivalent or tetravalent organic moiety;
R⁰, R⁰⁰, Y¹, and Y² are defined as shown above; and
n2=2, 3 or 4.

It is preferred that L²¹, L²², L²³, and L²⁴ are the same or different from each other and each independently is selected from OR″, F, Cl, Br and I.

It is more preferred that L²¹, L²², L²³, and L²⁴ are the same or different from each other and each independently is selected from OR″.

For R″ the preferred, more preferred, particularly preferred and most preferred definitions, as disclosed above for R′, apply, correspondingly.

In a preferred embodiment, R²¹, R²² and R²³ are the same or different from each other and each independently is selected from the group consisting of H, straight-chain alkyl having 1 to 20, preferably 1 to 12, carbon atoms, branched-chain alkyl having 3 to 20, preferably 3 to 12, carbon atoms, cyclic alkyl having 3 to 20, preferably 3 to 12, carbon atoms, and aryl having 6 to 14 carbon atoms, which optionally contain one or more functional groups selected from —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CR⁰═CR⁰⁰₂, —CY¹═CY²—, and —C═C—, and

wherein one or more H atoms are optionally replaced by F.

In a more preferred embodiment, R²¹, R²² and R²³ are selected from the group consisting of H, straight-chain alkyl having 1 to 12 carbon atoms, branched-chain alkyl having 3 to 12 carbon atoms, cyclic alkyl having 3 to 12 carbon atoms, and aryl having 6 to 14 carbon atoms, which optionally contain one or more functional groups selected from —C(═O)—, —C(═O)—O—, —O—C(═O)—, —CR⁰═CR⁰⁰—, —CR⁰═CR⁰⁰₂, and —CY¹═CY²—, and wherein one or more H atoms are optionally replaced by F.

In a particularly preferred embodiment R²¹, R²² and R²³ are selected from the group consisting of —CH₃, —CF₃, —C₂H₅, —C₂F₅, —C₃H₇, —C₃F₇, —C₄H₉, —C₄F₉, —C₅H₁₁, —C₅H₄F₇, —C₆H₁₃, —C₆H₄F₉, —C₇H₁₅, —C₇H₄F₁₁, —C₈H₁₇, —C₈H₄F₁₃, —CH═CH₂, —C(CH₃)═CH₂, —C₃H₆—O—C(═O)—CH═CH₂, —C₃H₆—O—C(═O)—C(CH₃)═CH₂, —C₆H₅, and —C₆F₅.

In a most preferred embodiment, R²¹, R²² and R²³ are selected from —CH₃, or —C₂H₅.

In a preferred embodiment, Z² denotes a straight-chain alkylene group having 1 to 12 carbon atoms, a branched-chain alkylene group having 3 to 12 carbon atoms or a cyclic alkylene group having 3 to 12 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡O—, and in which one or more H atoms are optionally replaced by F.

In a more preferred embodiment, Z² denotes a straight-chain alkylene group having 1 to 12 carbon atoms, which is selected from —(CH₂)—, —(CH₂)₂—, —(CH₂)₃—, —(CH₂)₄—, —(CH₂)₅—, —(CH₂)₆—, —(CH₂)₇—, —(CH₂)₈—, —(CH₂)₉—, —(CH₂)₁₉—, —(CH₂)₁₁—, and —(CH₂)₁₂—.

In a preferred embodiment, W² is represented by one of the Structures W1 to W4 as defined above.

Preferred third siloxane monomers are represented by one of the following structures:

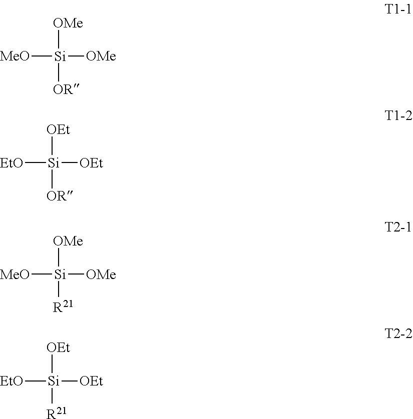

wherein:
R″ and R²¹ have one of the meanings as defined above.

More preferred third siloxane monomers are represented by one of the following structures:

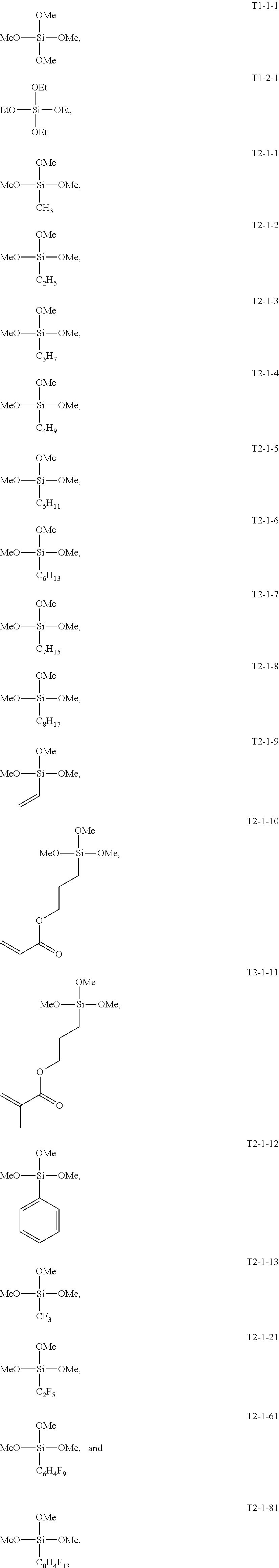

### Fourth Siloxane Monomer

In a more preferred embodiment, the monomer composition according to the present invention further comprises:

(d) a fourth siloxane monomer;
wherein the fourth siloxane monomer is different from the first siloxane monomer, the second siloxane monomer and the third siloxane monomer.

Preferably, the fourth siloxane monomer is represented by one of the following Structures F1 to F5:

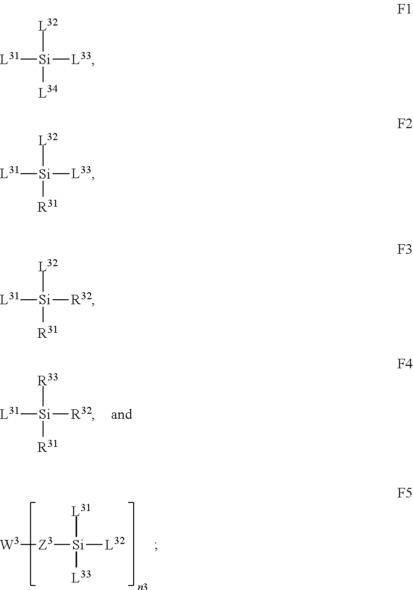

wherein:
L³¹, L³², L³³, and L³⁴ are the same or different from each other and each independently is selected from OR′″ and halogen;
R′″ is selected from the group consisting of straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C═C—, and wherein one or more H atoms are optionally replaced by F;
R³¹, R³² and R³³ are the same or different from each other and each independently is selected from the group consisting of H, straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, which optionally contain one or more functional groups selected from —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CR⁰═CR⁰⁰₂, —CY¹═CY²—, and —C═C—, and
wherein one or more H atoms are optionally replaced by F;
Z³ denotes a straight-chain alkylene group having 1 to 20 carbon atoms, a branched-chain alkylene group having 3 to 20 carbon atoms or a cyclic alkylene group having 3 to 20 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C═C—, and in which one or more H atoms are optionally replaced by F;
W³ denotes a divalent, trivalent and tetravalent organic moiety;
R⁰, R⁰⁰, Y¹, and Y² are defined as shown above; and
n3=2, 3 or 4.

It is preferred that L³¹, L³², L³³, and L³⁴ are the same or different from each other and each independently is selected from OR′″, F, Cl, Br and I.

It is more preferred that L³¹, L³², L³³, and L³⁴ are the same or different from each other and each independently is selected from OR′″.

For R′″ the preferred, more preferred, particularly preferred and most preferred definitions, as disclosed above for R′, apply, correspondingly.

In a preferred embodiment, R³¹, R³² and R³³ are the same or different from each other and each independently is selected from the group consisting of H, straight-chain alkyl having 1 to 20, preferably 1 to 12, carbon atoms, branched-chain alkyl having 3 to 20, preferably 3 to 12, carbon atoms, cyclic alkyl having 3 to 20, preferably 3 to 12, carbon atoms, and aryl having 6 to 14 carbon atoms, which optionally contain one or more functional groups selected from —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CR⁰═CR⁰⁰₂, —CY¹═CY²—, and —C═C—, and

wherein one or more H atoms are optionally replaced by F.

In a more preferred embodiment, R³¹, R³² and R³³ are selected from the group consisting of H, straight-chain alkyl having 1 to 12 carbon atoms, branched-chain alkyl having 3 to 12 carbon atoms, cyclic alkyl having 3 to 12 carbon atoms, and aryl having 6 to 14 carbon atoms, which optionally contain one or more functional groups selected from —C(═O)—, —C(═O)—O—, —O—C(═O)—, —CR⁰═CR⁰⁰—, —CR⁰═CR⁰⁰₂, and —CY¹═CY²—, and wherein one or more H atoms are optionally replaced by F.

In a particularly preferred embodiment R³¹, R³² and R³³ are selected from the group consisting of —CH₃, —CF₃, —C₂H₅, —C₂F₅, —C₃H₇, —C₃F₇, —C₄H₉, —C₄F₉, —C₅H₁₁, —C₅H₄F₇, —C₆H₁₃, —C₆H₄F₉, —C₇H₁₅, —C₇H₄F₁₁, —C₈H₁₇, —C₈H₄F₁₃, —CH═CH₂, —C(CH₃)═CH₂, —C₃H₆—O—C(═O)—CH═CH₂, —C₃H₆—O—C(═O)—C(CH₃)═CH₂, —C₆H₅, and —C₆F₅.

In a most preferred embodiment, R³¹, R³² and R³³ are selected from —CH₃, or —C₂H₅.

In a preferred embodiment, Z³ denotes a straight-chain alkylene group having 1 to 12 carbon atoms, a branched-chain alkylene group having 3 to 12 carbon atoms or a cyclic alkylene group having 3 to 12 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡O—, and in which one or more H atoms are optionally replaced by F.

In a more preferred embodiment, Z³ denotes a straight-chain alkylene group having 1 to 12 carbon atoms, which is selected from —(CH₂)—, —(CH₂)₂—, —(CH₂)₃—, —(CH₂)₄—, —(CH₂)₅—, —(CH₂)₆—, —(CH₂)₇—, —(CH₂)₈—, —(CH₂)₉—, —(CH₂)₁₀—, —(CH₂)₁₁—, and —(CH₂)₁₂—.

In a preferred embodiment, W³ is represented by one of the Structures W1 to W4 as defined above.

Preferred fourth siloxane monomers are represented by one of the following structures:

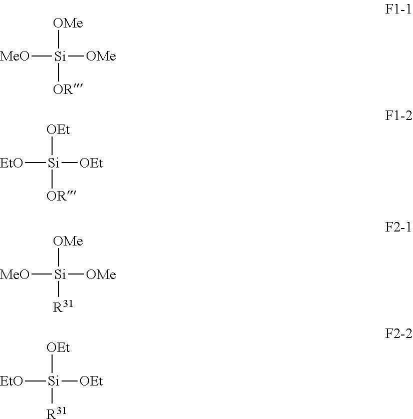

wherein:
R′″ and R³¹ have one of the meanings as defined above.

More preferred fourth siloxane monomers are represented by one of the following structures:

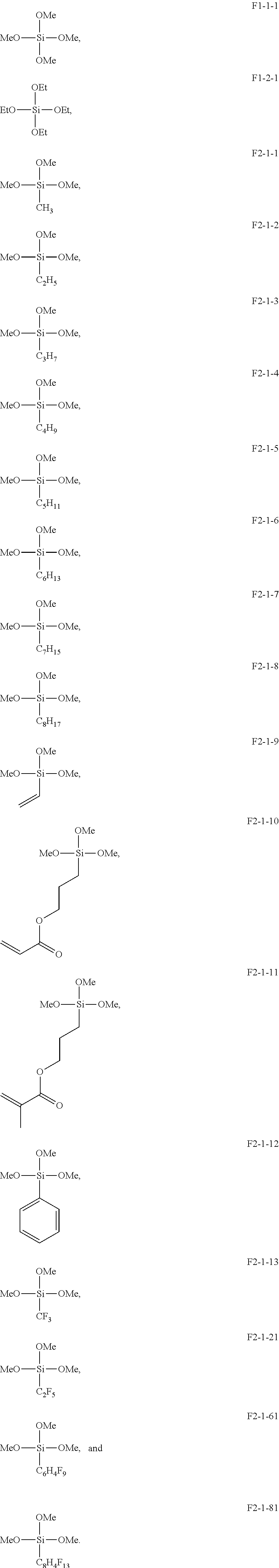

It is preferred that the molar ratio between the first siloxane monomer and the entirety of all further siloxane monomers, including at least the second siloxane monomer, in the monomer composition according to the present invention is in the range from 1:0.1 to 1:10, more preferably from 1:0.1 to 1:5, particularly preferably from 1:0.5 to 1:4, and most preferably from 1:1 to 1:3.

It is preferred that the monomer composition according to the present invention comprises one or more solvents.

### Method for Preparing Siloxane Polymer

In a second aspect, the present invention provides a method for preparing a siloxane oligomer or polymer, wherein the method comprises the following steps:

(i) providing a monomer composition according to the present invention; and
(ii) reacting the monomer composition provided in step (i) to obtain a siloxane oligomer or polymer.

It is preferred that the monomer composition provided in step (i) comprises a solvent. Suitable solvents are polar solvents, such as e.g. alcohol solvents, and ester solvents. Preferred alcohol solvents are ethanol, propan-1-ol, propan-2-ol, and propylene glycol methyl ether (PGME). Preferred ester solvents are 1-methoxy-2-propylacetat (PGMEA).

It is preferred that the monomer composition reacts in step (ii) in the presence of a base, such as e.g. tetramethylammonium hydroxide, tetraethylammonium hydroxide, tetrabutylammonium hydroxide, choline hydroxide, alkali metal hydroxide and diazabicycloundecene (DBU).

It is preferred that the monomer composition reacts in step (ii) under an inert gas atmosphere, such as e.g. a nitrogen and/or argon atmosphere.

It is preferred that the reaction temperature for step (ii) is controlled not to exceed 50° C., more preferably not to exceed 25° C.

The reaction time required for step (ii) is determined by turnover control. The reaction time is usually up to 6 hours, preferably up to 4 hours, more preferably up to 2 hours.

### Siloxane Oligomer and Polymer

In a third aspect, there is provided a siloxane oligomer or polymer, which is obtained or obtainable by the method for preparing a siloxane oligomer or polymer according to the present invention.

There is further provided a siloxane oligomer or polymer, comprising or consisting of a first repeating unit, wherein the first repeating unit is derived from a first siloxane monomer, and wherein the first siloxane monomer comprises a substituted or unsubstituted maleimide group. For the first siloxane monomer, the definitions above apply, accordingly.

It is preferred that the siloxane oligomer or polymer comprises a first repeating unit and a second repeating unit, wherein the first repeating unit is derived from a first siloxane monomer and the second repeating unit is derived from a second siloxane monomer, wherein the first siloxane monomer comprises a substituted or unsubstituted maleimide group; and wherein the second siloxane monomer is different from the first siloxane monomer. For the second siloxane monomer, the definitions above apply, accordingly.

It is further preferred that the siloxane oligomer or polymer further comprises a third repeating unit, wherein the third repeating unit is derived from a third siloxane monomer, wherein the third siloxane monomer is different from the first siloxane monomer and the second siloxane monomer. For the third siloxane monomer, the definitions above apply, accordingly.

Finally, it is further preferred that the siloxane oligomer or polymer further comprises a fourth repeating unit, wherein the fourth repeating unit is derived from a fourth siloxane monomer, wherein the fourth siloxane monomer is different from the first siloxane monomer, the second siloxane monomer and the third siloxane monomer. For the fourth siloxane monomer, the definitions above apply, accordingly.

The expression “derived from a siloxane monomer” means that the related repeating unit is formed by a condensation reaction of the siloxane monomer with another monomer, usually while retaining characteristic structural features of the siloxane monomer in the associated repeating unit forming part of the siloxane oligomer or polymer.

It is preferred that the siloxane oligomer or polymer according to the present invention is obtained or obtainable by the method for preparing a siloxane oligomer or polymer according to the present invention.

Depending on the number of different repeating units present in the oligomer or polymer, the compound may be a homopolymer or a copolymer.

The siloxane oligomers or polymers of the present invention may have a linear and/or branched structure. Branched structures include, e.g. ladders, closed cages, open cages and amorphous structures.

Preferably, the siloxane oligomers or polymers according to the present invention have a molecular weight M_{w}, as determined by GPC, of at least 500 g/mol, more preferably of at least 1,000 g/mol, even more preferably of at least 2,000 g/mol. Preferably, the molecular weight M_{w} of the siloxane oligomers or polymers is less than 50,000 g/mol, more preferably less than 30,000 g/mol, even more preferably less than 10,000 g/mol.

### Crosslinkable Composition

In a fourth aspect, the present invention provides a crosslinkable oligomer or polymer composition which comprises one or more siloxane oligomer(s) or polymer(s) according to the present invention.

The crosslinkable composition preferably comprises one or more solvents.

It is preferred that the crosslinkable composition comprises one or more initiators, such as e.g. photochemically activated initiators or thermally activated initiators. Preferred photochemically activated initiators are photoinitiators which create reactive species, such as e.g. free radicals, cations or anions, when exposed to radiation, such as e.g. UV or visible light. Suitable photoinitiators are e.g. Omnipol TX and Speedcure 7010.

Preferred thermally activated initiators are thermal initiators which create reactive species, such as e.g. free radicals, cations or anions, when exposed to heat.

In a particularly preferred embodiment of the present invention, the crosslinkable oligomer or polymer composition comprises a photoinitiator.

The total amount of initiator in the crosslinkable composition is preferably in the range from 0.01 to 10 wt.-%, more preferably from 0.5 to 5 wt.-%, based on the total weight of siloxane polymer.

The crosslinkable composition of the present invention may comprise one or more additives, selected from diamines, diols, dicarboxylic acids, polyhedral oligomeric silsesquioxanes (POSSs), edge-modified silsesquioxanes, small aromatic or aliphatic compounds, and nanoparticles, which may be optionally modified with maleimide- or dimethyl maleimide groups.

Modified POSS compounds can be readily prepared from available precursors, and are easily incorporated into the crosslinkable composition by appropriate mixing conditions. For example, maleimide substituted POSS compounds and their preparation are described in US 2006/0009578 A1 the disclosure of which is herewith incorporated by reference.

Preferred Additives are Selected from:

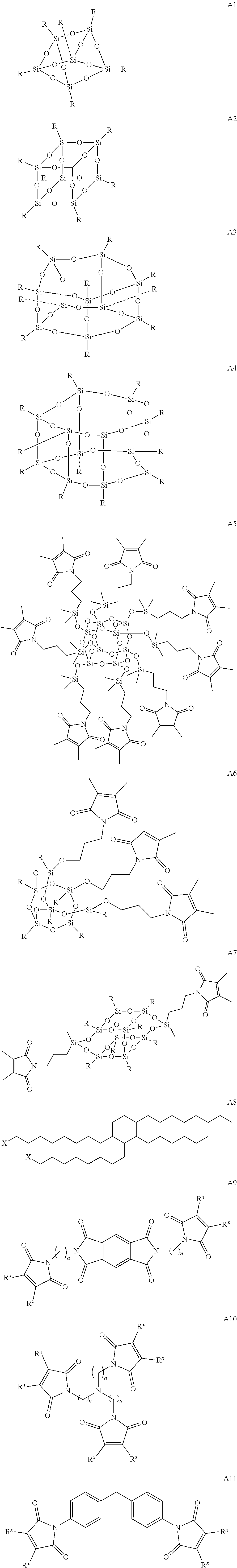

wherein:

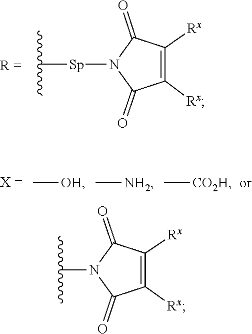

Sp=—CH₂—, —CH₂CH₂—, —CH₂CH₂CH₂—, —CH₂CH₂CH₂CH₂—, or —Si(CH₃)₂—CH₂—CH₂—CH₂—;
R^{x}═H, —CH₃, CF₃, CN or —CH₂CH₃; and
n=1 to 36, preferably 1 to 20, more preferably 1 to 12.

### Method for Manufacturing Microelectronic Structure

In a fifth aspect, the present invention provides a method for manufacturing a microelectronic structure, preferably a packaged microelectronic structure, a FET structure or a TFT structure, comprising the following steps:
(1) applying a crosslinkable oligomer or polymer composition according to the present invention to a surface of a substrate, preferably to a surface of a conducting or semiconducting substrate; and
(2) curing said crosslinkable oligomer or polymer composition to form a layer which passivates and optionally planarizes the surface of the substrate.

It is preferred that the surface of the substrate to which the crosslinkable oligomer or polymer composition is applied in step (1) is made of a conducting or semiconducting material. Preferred conducting materials are metals such as e.g. aluminium, molybdenum, titanium, nickel, copper, silver, metal alloys and so on. Preferred semiconducting materials are metal oxides such as indium gallium zinc oxide (IGZO), indium zinc oxide (IZO) or amorphous silicon and poly silicon.

It is preferred that the crosslinkable composition, which is applied in step (1), comprises one or more initiators. Preferred initiators are described above.

It is preferred that the crosslinkable composition further comprises one or more inorganic filler materials. Preferred inorganic filler materials are selected from nitrides, titanates, diamond, oxides, sulfides, sulfites, sulfates, silicates and carbides which may be optionally surface-modified with a capping agent. More preferably, the filler material is selected from the list consisting of AlN, Al₂O₃, BN, BaTiO₃, B₂O₃, Fe₂O₃, SiO₂, TiO₂, ZrO₂, PbS, SiC, diamond and glass particles.

Preferably, the total content of the inorganic filler material in the crosslinkable composition is in the range from 0.001 to 90 wt.-%, more preferably 0.01 to 70 wt.-% and most preferably 0.01 to 50 wt.-%, based on the total weight of the composition.

In case the crosslinkable composition contains a solvent, it is preferred that said solvent is removed by heating, more preferably by heating to 80 to 120° C., after said composition has been applied to the surface of the substrate.

The method by which the crosslinkable composition is applied in step (1) is not particularly limited. Preferred application methods for step (1) are dispensing, dipping, screen printing, stencil printing, roller coating, spray coating, slot coating, slit coating, spin coating, stereolithography, gravure printing, flexo printing or inkjet printing.

The crosslinkable oligomer or polymer composition of the present invention may be provided in the form of a formulation suitable for gravure printing, flexo printing and/or ink-jet printing. For the preparation of such formulations, ink base formulations as known from the state of the art can be used.

Alternatively, the crosslinkable oligomer or polymer composition of the present invention may be provided in the form of a formulation suitable for photolithography. The photolithography process allows the creation of a photopattern by using light to transfer a geometric pattern by means of a photomask to a photopatternable composition. Typically, such photopatternable composition contains a photochemically activatable initiator. For the preparation of such formulations, photoresist base formulations as known from the state of the art can be used.

It is preferred that the crosslinkable composition is applied in step (1) as a layer having an average thickness of about 0.1 to 50 μm, more preferably of about 0.5 to 20 μm, and most preferably of about 1 to 5 μm.

It is preferred that the curing in step (2) is carried out photochemically by exposure to radiation, such as e.g. UV or visible light, and/or thermally by exposure to heat. It is more preferred that the curing in step (2) is carried out photochemically by exposure to UV light and thermally by exposure to heat.

Exposure to radiation involves exposure to visible light and/or UV light. It is preferred that the visible light is electromagnetic radiation with a wavelength from >380 to 780 nm, more preferably from >380 to 500 nm. It is preferred that the UV light is electromagnetic radiation with a wavelength of 380 nm, more preferably a wavelength from 100 to 380 nm. More preferably, the UV light is selected from UV-A light having a wavelength from 315 to 380 nm, UV-B light having a wavelength from 280 to 315 nm, and UV-C light having a wavelength from 100 to 280 nm.

As UV light sources Hg-vapor lamps or UV-lasers are possible, as IR light sources ceramic-emitters or IR-laser diodes are possible and for light in the visible area laser diodes are possible.

In a preferred embodiment, the light source is a xenon flash light. Preferably, the xenon flash light has a broad emission spectrum with a short wavelength component going down to about 200 nm.

Exposure to heat involves exposure to an elevated temperature, preferably in the range from 100 to 300° C., more preferably from 150 to 250° C., and most preferably from 180 to 230° C.

### Electronic Device

In a sixth aspect, the present invention provides an electronic device, preferably a packaged microelectronic device, a FET array panel or a TFT array panel, which comprises a microelectronic structure, obtainable by the method for manufacturing a microelectronic structure according to the present invention.

For the electronic device it is preferred that the cured layer obtained from the crosslinkable composition passivates and optionally planarizes the surface of the substrate which forms part of the microelectronic structure. The formed layer is a dielectric layer which serves to electrically separate one or more electronic components of the electronic device from each other.

In a preferred embodiment, the dielectric layer forms part of a redistribution layer in a packaged microelectronic device.

It is also preferred that the siloxane oligomer or polymer of the present invention is used for the preparation of dielectric materials for redistribution layers (RDLs) in wafer-level packaging or panel-level packaging.

The present invention is further illustrated by the examples following hereinafter which shall in no way be construed as limiting. The skilled person will acknowledge that various modifications, additions and alternations may be made to the invention without departing from the spirit and scope of the invention as defined in the appended claims.

### Examples

### Measurement Methods

NMR Spectroscopy: NMR samples were measured in 3.7 mm (Ø_{A}) FEP inliner placed inside a 5 mm (Ø_{A}) thin-walled precision glass NMR tube (Wilmad 537 PPT), which contained CD₃CN in the annular space, or internally as dry solvent in 5 mm (Ø_{A}) precision glass NMR tubes. The measurements were carried out at 25° C. on a Bruker Avance III 400 MHz spectrometer equipped with a 9.3980 T cryomagnet. The ¹H NMR spectra were acquired using a 5 mm combination ¹H/¹⁹F probe operating at 400.17 and 376.54 MHz, respectively. The ¹³C, and ²⁹Si NMR spectra were obtained using a 5 mm broad-band inverse probe operating at 100.62 and 79.50 MHz, respectively. Line-broadening parameters used in exponential multiplication of the free induction decays were set equal to or less than their respective data-point resolutions or the natural line widths of the resonances. All line-shape functions were Lorentzian unless specified otherwise. In some cases, the free induction decays were multiplied by Gaussian functions for resolution enhancement on Fourier transformation. The ¹H NMR chemical shifts were referenced with respect to tetramethylsilane (TMS) yielding the following chemical shifts for the used solvents CDCl₃ (7.23 ppm), DMSO-d6 (2.50 ppm) and CD₂HCN (1.96 ppm). The ¹³C NMR spectra were referenced with respect to tetramethylsilane (TMS) using the chemical shifts for the solvents CDCl₃ (77.2 ppm), DMSO-d6 (39.5 ppm) and CD₃CN (118.7 ppm). The ²⁹Si NMR chemical shifts were referenced with respect to SiCl₄. A positive (negative) sign denotes a chemical shift to high (low) frequency of the reference compound.

DSC: Thermoanalytical data were achieved on a TA Instruments DSC Q100 using a Tzero cell design and operating at a temperature range from −90 to 725° C. with a temperature accuracy of ±0.1° C. and a calorimetric precision of ±1%. The samples were presented in sealed aluminum pans and heated using temperature programs. A usual program consists of a ramp with 5 k/min starting from 25° C. to 450° C. or with 10 K/min from 0° C. to 450° C.

FT-IR: FT-IR spectra were recorded with a Bruker ALPHA Platinum-ATR FT-IR with diamond crystal.

E2B: Flexible low-force measurements were carried out on a Zwick Roell Zwicki 500N system. The elongation to break measurements were performed at a pre-load at 0.1 N, the speed of elongation was set to 50 mm/min. A specimen suitable for measurement need to be 15 mm broad and 25 mm long.

CTE: The thermomechanical analysis was carried out on a Netzsch TMA 402 F1/F3 Hyperion equipped with a highly precise inductive displacement transducer, a precise force control system and a vacuum-tight thermostatic measuring system. A specimen suitable for measurement has to be a uniform free-standing film. The measurement was performed in nitrogen at a flow rate of 50 mL/min. The static force of the instrument used was 0.05 N and the sampling rate was 75 points/min. The temperature of each measurement was from 20° C. to 300° C. with a heating-rate of 5 K/min. Each temperature ramp was measured twice and the second measurement was evaluated.

GPC analysis: Gel permeation chromatographic (GPC) analysis was carried out on an Agilent 1260 Infinity II liquid chromatography system equipped with a refractive index detector. The column (Agilent MesoPore PL1113-6325) was eluted with tetrahydrofuran at a flow rate of 1.0 cm³/min and temperature of 40° C. A series of 12 narrow-dispersity polystyrene standards was used to calibrate the GPC system.

Mechanical properties: Polysiloxane oligomers were prepared freshly in PGMEA solvent of different concentrations (20-50 wt.-%). This solution was either spin coated, doctor bladed or drop casted into different molds. The material is then thermally cured and/or irradiated with UV light in different ways. The specimen or free-standing films were subsequently measured using the named apparatus.

Profilometer (stylus type): High resolution 2D profiling of developed specimen were carried out on a KLA Tencor Alpha-step D-500 equipped with an optical lever sensor technology. The 140 mm sample stage supports scan lengths up to 30 mm in a single scan and up to 80 mm utilizing the stitching function. The D-500 provides the highest vertical range at 1200 μm and low force sensor technology at 0.03 mg, ensuring scan precision on an array of applications, including thin films, soft materials, tall steps, bow, and stress. Samples depicted here were measured at a stylus radius of 2 μm and a stylus force of 1 mg.

UV Lamps: 365 nm and 254 nm. Curing of material was carried out using a UVP Transilluminator from Analytic Jena equipped with 8-Watt UV bulbs of 302 nm and 365 nm and a filter sizes of 20 cm×20 cm.

### Synthesis of Monomers

### 1-Allyl-3,4-di methyl-pyrrole-2,5-dione

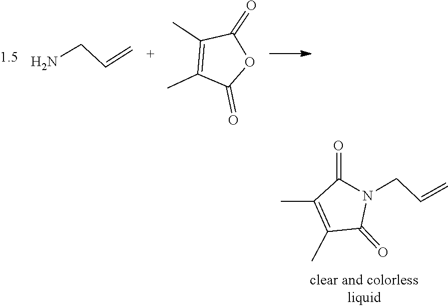

In a 250-mL round bottom flask equipped with a Dean Stark trap 3,4-dimethyl-furan-2,5-dione (160.0 g; 1243.4 mmol; 1.0 eq.) was dissolved in anhydrous toluene (1040 mL; 9.8 mol; 7.90 eq.). The mixture was stirred at RT until completely dissolved. A solution of allyl amine (139.9 ml; 1865.0 mmol; 1.5 eq.) in anhydrous toluene (160.0 ml; 1.5 mol; 1.2 eq.) was added by means of a dropping funnel at 23° C. The solution was warmed (140° C., reflux) and stirred for 5 hours at 140° C. With time a white solid precipitated. The mixture was subsequently cooled to RT and toluene removed in vacuum (10 mbar) at 70° C. Liquid, clear and pale orange crude product (222 g) was isolated. After fractional condensation in vacuum (10⁻² mbar) at 120° C. clear and colorless product, 1-Allyl-3,4-dimethyl-pyrrole-2,5-dione (201.2 g; 1.169 mmol) was isolated in 94% yield and 96% purity. The product was stored at low temperature (4° C.).

¹H-NMR (400.17 MHz, DMSO, δ in ppm): 1.92 (s, 6H, CH₃); 4.01 (dt, ³J_{HH}=5.1 Hz, ⁴J_{HH}=1.7, 2H, CH₂); 5.05 (ddt, ³J_{trans-HH}=17.1 Hz, ²J_{HH}=3.1 Hz, ⁴J_{HH}=1.5 Hz, 1H, CH₂═CH); 5.08 (ddt, ³J_{cis-HH}=10.3 Hz, ²J_{HH}=3.1 Hz, ⁴J_{HH}=1.5 Hz, 1H, CH₂═CH); 5.79 (ddt, ³J_{trans-HH}=17.1 Hz, ³J_{cis-HH}=10.3 Hz, ³J_{HH}=5.1 Hz, 1H, CH₂═CH). ¹³C-NMR (100.62 MHz, CDCl₃, δ in ppm): 8.62 (q, ¹J_{CH}=129.5 Hz, CH₃); 39.92 (td, ¹J_{CH}=140.3 Hz, ²J_{CH}=8.0 Hz, ²J_{CH}=5.5 Hz, CH₂); 117.18 (ddt, ¹J_{CH}=159.4 Hz, ¹J_{CH}=155.3 Hz, ³J_{CH}=5.5 Hz, CH₂); 132.01 (dtd, ¹J_{CH}=157.7 Hz, ²J_{CH}=5.5 Hz, ²J_{CH}=3.0 Hz, CH); 137.18 (qq, ²J_{CH}=7.5 Hz, ³J_{CH}=5.7 Hz, C═C); 171.6 (m, C═O).

### 3,4-Dimethyl-1-(3-triethoxysilylpropyl)pyrrole-2,5-dione

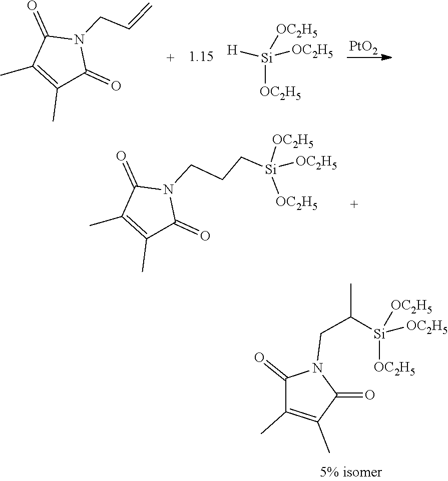

In a 500-mL round bottom flask equipped with a reflux-condenser pale yellow and liquid 1-Allyl-3,4-dimethyl-pyrrole-2,5-dione (100.0 g; 851.2 mmol; 1.0 eq.) was presented and platinum(IV)oxide (25.0 mg; 0.110 mmol, 1.15 eq.) and triethoxysilane (129.9 g; 668.3 mmol; 1.15 eq.) were added upon rigorous stirring at RT. The solution was warmed (80° C.) and stirred for 190 h at 80° C. The completion of the reaction was monitored by ¹H NMR spectroscopy. The solution was subsequently cooled to RT. Chloroform (100 mL) and active coal (8.0 g) were added and stirred for 1 h at RT. The suspension was subsequently filtered (paper filter and 0.45 μm PTFE filter) and the mother liquor distilled in vacuum (20 mbar) at 60° C. to remove the solvents. The product, 3,4-dimethyl-1-(3-triethoxysilylpropyl)pyrrole-2,5-dione (162 g) was isolated as clear and pale brown liquid. After fractional condensation in vacuum (0.2-0.35 mbar) at 130 to 140° C. clear and deep yellow material, beta 3,4-dimethyl-1-(2-triethoxysilylpropyl)pyrrole-2,5-dione (11.93 g; 36.2 mmol) was isolated in 6.2% yield and 96% purity. The desired product, gamma 3,4-dimethyl-1-(3-triethoxysilylpropyl)pyrrole-2,5-dione (147.6 g; 448 mmol) was isolated in vacuum (0.2 mbar) at 160° C. as clear and colorless liquid in 77% yield and 99% purity. The material was stored at low temperature (4° C.).

¹H-NMR (400.17 MHz, CD₃CN film, δ in ppm): −0.05 (m, 2H, CH₂); 0.61 (t, ³J_{HH}=7.0 Hz, 9H, CH₃); 1.04 (tt, ³J_{HH}=7.3 Hz, ³J_{HH}=resolution T1/2=2.5 Hz, 2H, CH₂); 1.36 (s, 6H, CH₃); 2.85 (t, ³J_{HH}=7.3, 2H, CH₂); 3.21 (q, ³J_{HH}=7.0 Hz, 6H, CH₂).

¹³C-NMR (100.62 MHz, CD₃CN film, δ in ppm): 6.69 (tt, ¹J_{CH}=117.1 Hz, ²J_{CH}=2.9 Hz, CH₂); 6.97 (q, ¹J_{CH}=128.9 Hz, CH₃); 17.08 (qt, ¹J_{CH}=125.8 Hz, ²J_{CH}=2.3 Hz, CH₃); 21.19 (tc, ¹J_{CH}=128.8 Hz, ²J_{CH}=resolution T1/2=12 Hz, CH₂); 39.10 (tt, ¹J_{CH}=139.7 Hz, ²J_{CH}=4.4 Hz, CH₂); 57.04 (tq, ¹J_{CH}=141.8 Hz, ²J_{CH}=4.5 Hz, CH₂); 135.65 (qq, ²J_{CH}=7.5 Hz, ³J_{CH}=5.7 Hz, C═C); 170.33 (m, C═O).

²⁹Si{¹H}-NMR (79.5 MHz, CDCl₃, δ in ppm): −46.0 (s).

### Octakis(3,4-dimethyl-pyrrole-2,5-dione propyl dimethylsiloxy)-T8-silsesquioxane

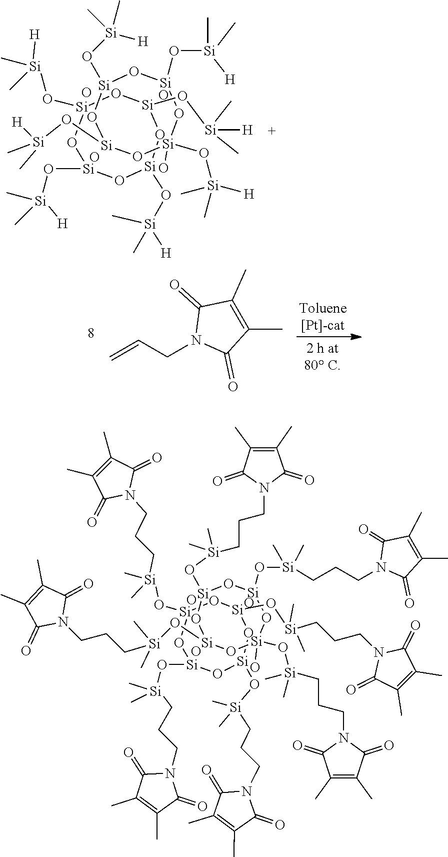

In a two necked 50-mL round bottom flask equipped with a reflux-condenser and nitrogen inlet pale yellow and liquid 1-allyl-3,4-dimethyl-pyrrole-2,5-dione (2.705 g; 15.7 mmol; 8.00 eq.) was presented and stirred at 400 rpm. In a separate flask white and solid octakis(dimethylsiloxy)-T8-silsesquioxane (2.000 g; 1.97 mmol; 1.00 eq.) was dissolved in dry toluene (20.0 ml; 0.189 mol; 96 eq.) and added in one portion to 1-allyl-3,4-dimethyl-pyrrole-2,5-dione. The solution was warmed to 80° C. Once 50° C. was reached, platinum(0)-1,3-divinyl-1,1,3,3-tetramethyldisiloxane complex solution in xylene (Pt ^{˜}2%; 100 μl) was added by means of a Hamilton syringe. The solution was stirred for two hours at 80° C. The solution turned yellow upon reaction time. The completion of the reaction was monitored by NMR spectroscopy. Subsequently, toluene and all volatile materials were removed in vacuum by means of a rotary evaporator (20 mbar) at 70° C. yielding a high viscous yellow liquid. The product, octakis(3,4-dimethyl-pyrrole-2,5-dione propyl dimethylsiloxy)-T8-silsesquioxane (4.6 g, 1.96 mmol) was isolated in nearly 100% yield.

¹H-NMR (400.17 MHz, CDCl₃, δ in ppm): 0.1 (s, 6H, CH₃); 0.54 (m, 2H, CH₂); 1.55 (m, 2H, CH₂); 1.91 (s, 6H, CH₃); 3.41 (t, ³J_{HH}=7.3 Hz, 2H, CH₂). ¹³C-NMR (100.62 MHz, CDCl₃, δ in ppm): −0.27 (q, ¹J_{CH}=118.19 Hz, CH₃); 8.77 (q, ¹J_{CH}=128.9 Hz, CH₃); 14.82 (m, CH₂); 22.5 (ttt, ¹J_{CH}=128.7 Hz, ²J_{CH}=5.0 Hz, ³J_{CH}=3.0 Hz, CH₂); 40.84 (ttt, ¹J_{CH}=139.5 Hz, ²J_{CH}=4.6-5.0 Hz, CH₂); 137.04 (qq, ²J_{CH}=7.5 Hz, ³J_{CH}=5.7 Hz, C═C); 172.32 (m, C═O).

### Tetrakis(3,4-dimethyl-pyrrole-2,5-dione propyl dimethylsiloxy) tetrakis(2-propyloxymethyl-oxiran)-T8-silsesquioxane

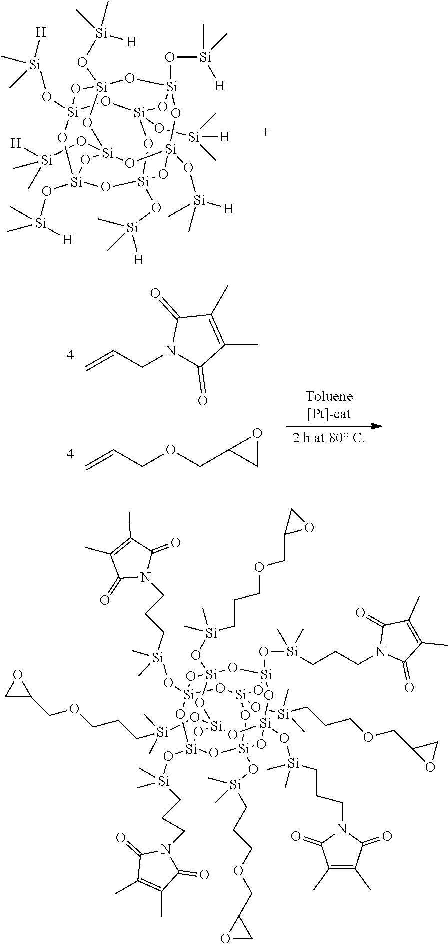

In a two necked 50-mL round bottom flask equipped with a reflux-condenser and nitrogen inlet pale yellow and liquid 1-allyl-3,4-dimethyl-pyrrole-2,5-dione (1.352 g; 7.86 mmol; 4.00 eq.) and 2-allyloxymethyl-oxirane (0.932 ml; 7.86 mmol; 4.0 eq.) was presented and stirred at 400 rpm. In a separate flask white and solid octakis(dimethylsiloxy)-T8-silsesquioxane (2.000 g; 1.97 mmol; 1.0 eq.) was dissolved in dry toluene (20.0 ml; 0.189 mol; 96 eq.) and added in one portion to 1-allyl-3,4-dimethyl-pyrrole-2,5-dione. The solution was warmed to 80° C. Once 50° C. was reached, platinum(0)-1,3-divinyl-1,1,3,3-tetramethyldisiloxane complex solution in xylene (Pt ^{˜}2%; 100 μl) was added by means of a Hamilton syringe. The solution was stirred for two hours at 80° C. The solution turned yellow upon reaction time. The completion of the reaction was monitored by NMR spectroscopy. Subsequently, toluene and all volatile materials were removed in vacuum by means of a rotary evaporator (20 mbar) at 70° C. yielding a high viscous yellow liquid. The product, Tetrakis(3,4-dimethyl-pyrrole-2,5-dione propyl dimethylsiloxy) tetrakis(2-propyloxymethyl-oxiran)-T8-silsesquioxane (4.2 g, 1.97 mmol) was isolated in nearly 100% yield.

¹H-NMR (400.17 MHz, CDCl₃, δ in ppm): 0.0 (m, 48H, CH₃^{DMMI/Epoxy}); 0.44 (m, 16H, CH₂^{DMMI/Epoxy})^{o}; 1.45 (m, 8H, CH₂^{DMMI}); 1.52 (m, 8H, CH₂^{Epoxy})^{o}; 1.82 (s, 24H, CH₃^{DMMI}); 3.0 (m, 4H, CH^{Epoxy}); 3.3 (m, 8H, CH₂^{Epoxy})^{o}; 3.3 (m, 4H, CH′H″^{Epoxy})^{o}; 3.31 (t, ³J_{HH}=7.3, 8H, CH₂^{DMMI})^{o}; 3.55 (d, ³J_{HH} 11.2 Hz, 4H, CH′H″^{Epoxy}). (^{o} overlaid)

¹³C-NMR (100.62 MHz, CDCl₃, δ in ppm): −0.26 (q, ¹J_{CH}=118.8 Hz, CH₃^{DMMI/Epoxy}); −0.21 (q, ¹J_{CH}=118.8 Hz, CH₃^{DMMI/Epoxy}); 8.8 (q, ¹J_{CH}=130.0 Hz, CH₃^{DMMI}); 13.8 (t, ¹J_{CH}=117.3 Hz, CH₂^{Epoxy}); 14.9 (t, ¹J_{CH}=117.3 Hz, CH₂^{DMMI}); 22.5 (tm, ¹J_{CH}=128.7 Hz, CH₂^{DMMI}); 23.34 (tm, ¹J_{CH}=126.6 Hz, CH₂^{Epoxy}); 40.8 (tqui, ¹J_{CH}=139.6 Hz, ²J_{CH}=4.5 Hz, CH₂^{DMMI}); 44.5 (t, ¹J_{CH}=175.1 Hz, CH₂^{Epoxy}); 51.0 (dm, ¹J_{CH}=174.1 Hz, CH₂^{Epoxy}); 71.6 (t, ¹J_{CH}=140.6 Hz, CH₂^{Epoxy}); 74.3 (tqui, ¹J_{CH}=140.4 Hz, ²J_{CH}=4.1 Hz, CH₂^{Epoxy}); 137.1 (qui, ²J_{CH}=6.6 Hz, C^{DMMI}); 172.3 (s, CO^{DMMI}).

²⁹Si-NMR (79.5 MHz, CDCl₃, δ in ppm): −109.1 (m, 8 SiO_{1.5}); 12.5 (m, 4 Si^{DMMI}); 12.9 (m, Si^{epoxy}),

T7iBu7(Si(CH₃)₂H)₃:

In a 250-mL round bottom flask, 1,3,5,7,9,11,14-heptaisobutyltricyclo [7.3.3.15,11] heptasiloxane-endo-3,7,14-triol (5.0 g, 6.3 mmol) was cooled (0° C.) and dissolved in dry cold THF (50 mL, 0° C.) under N₂ atmosphere and chlorodimethyl silane was added (2.02 g, 21.34 mmol), followed by dropwise addition of triethylamine (2.20 g, 21.73 mmol). The reaction was exothermic and formed white precipitate. The mixture was stirred for 2 h at 0° C. The suspension was then allowed to warm to RT and let to stir for further 20 h at RT. Subsequently, the suspension was filtered, and all volatile materials condensed off in vacuum (150-200 mbar) at 25° C. A white sticky solid was obtained and was washed with CH₃OH (3×10 mL). The solid material was finally dried in vacuum (10-40 mbar) at 35° C. The desired product, 3,7,14-tris[(dimethylsilyl)oxy]-1,3,5,7,9,11,14-heptakis(2-methylpropyl)tricyclo [7.3.3.15,¹¹] heptasiloxane (4.567 g; 4.73 mmol) was isolated as white solid in 74.8% yield. Further purification can be achieved by recrystallization from CH₃OH/CHCl₃ (3:2).

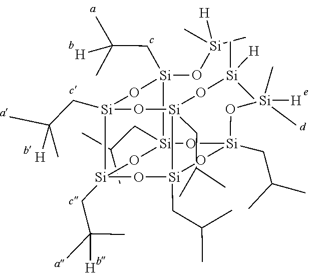 [SMILES: CC(C)C[Si]1(OC[SiH](C)C)O[Si]2(CC(C)C)O[Si]3(CC(C)C)O[Si](CC(C)C)(O1)[Si](CC(C)C)(O[SiH](C)C)O[Si]3(CC(C)C)O[Si]2(CC(C)C)O[SiH](C)C]

¹H-NMR (400.17 MHz, CDCl₃, δ in ppm): 0.19 (d, ³J_{HH}=2.8 Hz, 18H^{d}), 0.54 (d, ³J_{HH}=6.9 Hz, 14H^{c,c′c,″)}^{^{o}}^{,} 0.93 (dm, ³J_{HH}=6.7 Hz, ⁴J_{HH}=2.7 Hz, 42H^{a,a′,a″})^{o}, 1.81 (sepm, ³J_{HH}=6.7 Hz, 7H^{b,b′,b″})^{o}, 4.71 (sep, ³J_{HH}=6.7 Hz, 3H^{e}). (^{o} overlaid)

### T7iBu7(Si(CH₃)₂propylDMMI)₃

In a 250-mL round bottom flask, a solution of 3,7,14-tris[(dimethylsilyl)oxy]-1,3,5,7,9,11,14-heptakis(2-methylpropyl)tricyclo[7.3.3.15,¹¹]heptasiloxane (3.44 g, 3.56 mmol), 3,4-dimethyl-1-(prop-2-en-1-yl)-2,5-dihydro-1H-pyrrole-2,5-dione (1.69 g, 10.25 mmol) in dry toluene (20 mL) were stirred under N2 atmosphere at RT. Platinum(0)-1,3-divinyl-1,1,3,3-tetramethyldisiloxane complex in xylene (Pt ^{˜}2%, 0.23 mL, 0.51 mmol) (Karstedt catalyst) was added to the solution and heated to 90° C. The solution was refluxed for 1 h at 90° C. or until completion as monitored by disappearance of Si—H signal in FTIR (904 cm⁻¹). The post-reaction mixture was allowed to cool to RT before activated charcoal (0.5 g) was added and stirred for several hours at RT. The mixture was filtered through a bed of Celite and the filtrate isolated and all volatile materials condensed off in vacuum (150-200 mbar) at 25° C. The crude product appeared as golden-coloured liquid. Purification can be achieved using column chromatography (CH₂Cl₂/Light Petrol 40-60 (7:3) solvent system). All volatile materials were again condensed off in vacuum (150-200 mbar) at 25° C. from the relevant fractions, and further dried in vacuum (10-40 mbar) at 35° C. The desired product, 1-[3-({[7,14-bis({[3-(3,4-dimethyl-2,5-dioxo-2,5-dihydro-1H-pyrrol-1-yl)propyl]dimethylsilyl}oxy)-1,3,5,7,9,11,14-heptakis(2-methylpropyl)tricyclo[7.3.3.15,¹¹]heptasiloxan-3-yl]oxy}dimethylsilyl)propyl]-3,4-dimethyl-2,5-dihydro-1H-pyrrole-2,5-dione (2.8 g, 1.92 mmol), was isolated as a colourless liquid in 53.9% yield.

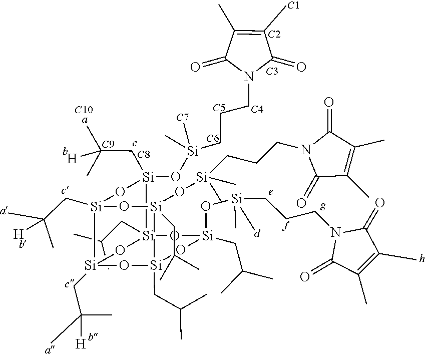

¹H-NMR (400.17 MHz, CDCl₃, δ in ppm): 0.07 (s, 18H^{d}), 0.48 (m, 6H^{e}), 0.53 (m, 14H^{c}), 0.95 (dd, ³J_{HH}=6.6 Hz, ⁴J_{HH}=1.6 Hz, 42H^{a}), 1.52 (m, 6H^{f}), 1.78 (dec, ³J_{HH}=6.7 Hz, 7H^{b}), 1.95 (s, 3H^{h}), 3.39 (t, ³J_{HH}=7.5 Hz, 6H^{g}).

¹³C-NMR (100.62 MHz, CDCl₃, δ in ppm): 0.41 (q, ¹J_{CH}=119.1 Hz, 6C⁷), 8.88 (q, ¹J_{CH}=129.1 Hz, 6C¹), 15.39 (t, ¹J_{CH}=116.7 Hz, 3C⁶), 22.87 (t, ¹J_{CH}=125.7 Hz, 6C⁵), 21.5-28.5 (i-Bu groups, 28C^{a-c,a′-c′,a″-c″})^{o} 41.05 (t, ¹J_{CH}=139.8 Hz, 3C⁴), 137.09 (q, ²J_{CH}=7.4 Hz, 6C²), 172.43 (m, 6C³).

### T7Ph7(Si(CH₃)₂H)₃

In a 250-mL round bottom flask, 1,3,5,7,9,11,14-heptaphenyltricyclo [7.3.3.15,11] heptasiloxane-endo-3,7,14-triol (5.0 g, 5.37 mmol) was dissolved in dry toluene (25 mL) under N2 atmosphere at 0° C. Chlorodi-methylsilane was added (1.72 g, 18.20 mmol) to this solution at 0° C., followed by dropwise addition of triethylamine (1.87 g, 18.48 mmol). The reaction was exothermic and formed white precipitate. The suspension was stirred for 2 h at 0° C. After that, the suspension was warmed to RT and let to stir for a further 20 hrs at RT. Subsequently, the suspension was filtered, and all volatile materials condensed off in vacuum (150-200 mbar) at 25° C. A white sticky solid was obtained and was washed with CH₃OH (3×10 mL). The solid material was finally dried in vacuum (10-40 mbar) at 35° C. The desired product, 3,7,14-tris[(dimethylsilyl)oxy]-1,3,5,7,9,11,14-heptaphenyl-tricyclo [7.3.3.15,¹¹] heptasiloxane (4.200 g; 3.80 mmol) was isolated as white solid in 70.7% yield. Further purification can be achieved by recrystallization from CH₃OH/CHCl₃ (3:2).

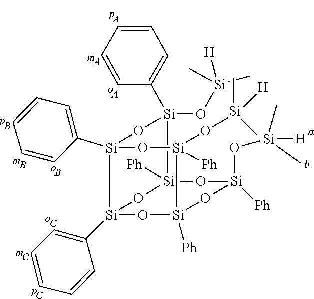

¹H-NMR (400.17 MHz, CDCl₃, δ in ppm): 0.35 (d, ³J_{HH}=2.8 Hz, 18H^{b}), 4.93 (sep, ³J_{HH}=2.8 Hz, 3H^{a}), 7.12 (tm, ³J_{HH}=8.0 Hz, 14H^{ma,b,c})^{o}, 7.28 (tm, ³J_{HH}=8.0 Hz, 6H^{pa,b})^{o}, 7.32 (dm, ³J_{HH}=8.0 Hz, 6H^{oa}), 7.42 (tm, ³J_{HH}=8.0 Hz, 1H^{pc}), 7.45 (dm, ³J_{HH}=8.0 Hz, 6H^{ob}), 7.59 (dm, ³J_{HH}=8.0 Hz, 2H^{oc}). (^{o} overlaid)

### T7Ph7(Si(CH₃)₂propylDMMI)₃

In a 250-mL round bottom flask, (3r,7s,11s)-3,7,14-tris[(dimethylsilyl)oxy]-1,3,5,7,9,11,14-heptaphenyltricyclo [7.3.3.15,¹¹] heptasiloxane (2.78 g, 2.52 mmol) and 3,4-dimethyl-1-(prop-2-en-1-yl)-2,5-dihydro-1H-pyrrole-2,5-dione (1.20 g, 7.26 mmol) were dissolved in dry THE (20 mL) under rigorous stirring under N2 atmosphere at RT. Platinum(0)-1,3-divinyl-1,1,3,3-tetramethyldisiloxane complex in xylene (Pt ^{˜}2%, 0.16 mL, 0.36 mmol) (Karstedt catalyst) was added to the solution heated to 90° C. The solution was refluxed for 1 h at 90° C. or until completion as monitored by disappearance of Si—H signal in FTIR (904 cm⁻¹). The post-reaction mixture was allowed to cool to RT before all volatile materials were condensed off in vacuum (150-200 mbar) at 25° C. The residue was redissolved in CHCl₃ (20 mL) and treated with 0.1 wt.-% activated charcoal (0.021 g, 1.75 mmol). The mixture was heated to reflux temperature and further refluxed for 18 h at 60° C. The mixture was then filtered through a bed of Celite, supported by cotton wool in a microcolumn. Subsequently, all volatile materials was condensed off in vacuum (150-200 mbar) at 25° C. The crude product appeared as golden-coloured viscous liquid. Purification can be achieved using column chromatography (CH₂Cl₂/Light Petrol 40-60 (7:3) solvent system). All volatile materials were again condensed off in vacuum (150-200 mbar) at 25° C. from the relevant fractions, and further dried in vacuum (10-40 mbar) at 35° C. The desired product, 1-{3-[dimethyl({[(7r,9r,11 s,14r)-7,14-bis({[3-(3,4-dimethyl-2,5-dioxo-2,5-dihydro-1H-pyrrol-1-yl)propyl]dimethylsilyl}oxy)-1,3,5,7,9,11,14-heptaphenyltricyclo [7.3.3.15,¹¹]heptasiloxan-3-yl]oxy})silyl]propyl}-3,4-dimethyl-2,5-dihydro-1H-pyrrole-2,5-dione (0.800 g, 0.50 mmol), was isolated as a colourless viscous liquid in 20% yield.

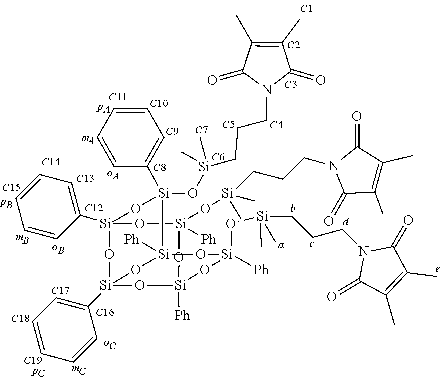

¹H-NMR (400.17 MHz, CDCl₃, δ in ppm): 0.25 (s, 18H^{e}), 0.56 (m, 6H^{b}), 1.53 (m, 6H^{c}), 1.93 (s, 18H^{a}),7.10 (tm, ³J_{HH}=8.0 Hz, 6H^{ma}), 7.15 (tm, ³J_{HH}=8.0 Hz, 6H^{mb}), 7.26 (tm, ³J_{HH}=8.0 Hz, 3H^{pa}), 7.29 (tm, ³J_{HH}=8.0 Hz, 3H^{pb}), 7.31 (dm, ³J_{HH}=8.0 Hz, 6H^{oa}), 7.41 (tm, ³J_{HH}=8.0 Hz, 1H^{pc}), 7.37 (dm, ³J_{HH}=8.0 Hz, 6H^{ob}), 7.54 (dm, ³J_{HH}=8.0 Hz, 2H^{oc}). (^{o} overlaid)

¹³C-NMR (100.62 MHz, CDCl₃, δ in ppm): 0.5 (q, ¹J_{CH}=119.1 Hz, 6C⁷), 8.9 (q, ¹J_{CH}=129.1 Hz, 6C¹), 15.4 (t, ¹J_{CH}=116.7 Hz, 3C⁶), 22.8 (t, ¹J_{CH}=125.7 Hz, 3C⁵), 40.5 (t, ¹J_{CH}=141 Hz, C⁵), 127.7 (dm, ¹J_{CH}=161.1 Hz, 2C¹⁰), 127.8 (dm, ¹J_{CH}=161 Hz, 2C¹⁴), 128.1 (m, 2C¹⁸), 130.2 (m, 2C¹¹)^{o}, 130.8 (m, 2C¹⁵)^{o}, 131.3 (m, 2C¹⁹)^{o}, 132.8 (m, 2C¹⁷)^{o}, 134.1 (dm, ¹J_{CH}=157 Hz, 2C⁹), 134.2 (dm, ¹J_{CH}=158 Hz, 2C¹³), 137.1 (s, 6C²), 172.4 (s, 6C³). (^{o} overlaid)

### Priamine-bis(3,4-dimethyl-pyrrole-2,5-dione)

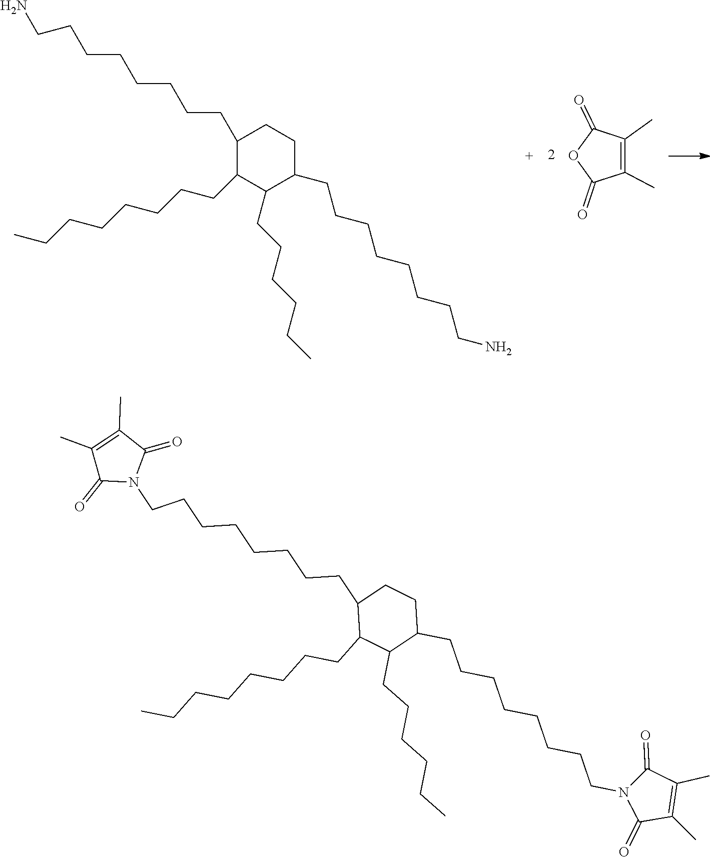

In a 250 mL round bottom flask equipped with a dropping funnel and a Dean Stark trap 8-[2-(8-Amino-octyl)-3-hexyl-4-octyl-cyclohexyl]-octylamine (Priamine) (81.00 g; 149.9 mmol; 1.00 eq.) was dissolved in dry toluene (max. 75 ppm H₂O) SeccoSolv® (480.00 ml; 4.5 mol; 30.2 eq.) and stirred at RT until dissolved using a magnetic stirrer. A solution of 3,4-Dimethyl-furan-2,5-dione (DMMA) (38.58 g; 299.78 mmol; 2.00 eq.) in dry toluene (max. 75 ppm H₂O) SeccoSolv® (400.0 ml; 3.78 mol; 25.20 eq.) was presented in the dropping funnel and added to the priamine solution at RT whereupon a white solid precipitated upon time. The reaction suspension was heated to 140° C. (reflux) and stirred for 5 h at 140° C. Water was separated in the Dean Stark trap. The reaction was allowed to cool to RT before residual toluene was removed in vacuum (˜10 mbar) at 70° C. The product, 1-[8-[2-[8-(3,4-dimethyl-2,5-dioxo-pyrrol-1-yl)octyl]-3-hexyl-4-octyl-cyclohexyl]octyl]-3,4-dimethyl-pyrrole-2,5-dione (109.43 g; 145.7 mmol; 97% yield) was isolated as clear and orange liquid.

¹H-NMR (400.17 MHz, CDCl₃, δ in ppm): 0.74 bis 0.95 (m, 8H, CH und CH₃); 1.03 bis 1.41 (m, 52H, CH₂); 1.54 (q, ³J_{HH}=6.6, 6H, CH und CH₂); 1.94 (s, 12H, CH₃); 3.45 (t, ³J_{HH}=7.3, 4H, CH₂).

¹³C-NMR (100.62 MHz, CDCl₃, δ in ppm): 8.6 (q, ¹J_{CH}=129.0 Hz, CH₃); 14.1 (qm, ¹J_{CH}=124.7 Hz, CH₂); 22.6 (tm, ¹J_{CH}=125.7 Hz, CH₂); 26.8, 28.7, 29.2, 29.3, 29.5, 29.6, 29.66, 29.7 (m, CH₂)^{o}; 37.9 (tm, ¹J_{CH}=139.6 Hz, CH₂); 136.95 (q, ²J_{CH}=6.6 Hz, C); 172.3 (s, CO).

### Pyromellitic bis[3-(trimethoxysilyl)propyl]imide

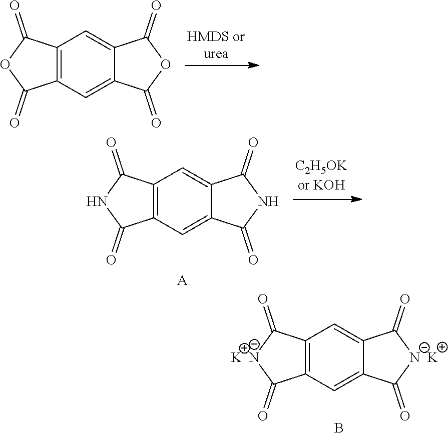

In a 100-mL round bottom flask equipped with a reflux condenser and a nitrogen inlet a premix of benzo[1,2-c;4,5-c′]difuran-1,3,5,7-tetraone (4.570 g; 20.950 mmol; 1.00 eq.) and urea (9.322 ml; 208.0 mmol; 9.93 eq.) was heated to 200° C. The solution was stirred for 2 h at 200° C. A white solid precipitated upon time. After 2 h the solid was filtered off and grounded into a powder. The powder was stirred for another 1 h at 200° C. After cooling to RT the powder was washed several times using distilled water. Subsequently, the white powder was dried for several hours in vacuum (10 mbar) at 100° C. The desired product A, pyrrolo[3,4-f]isoindole-1,3,5,7-tetraone (4.49 g; 20.8 mmol; 99%) was isolated as white solid. In a three necked 250 mL round bottom flask equipped with a condenser and nitrogen inlet pyrrolo[3,4-f]isoindole-1,3,5,7-tetraone (13.927 g; 0.063 mol; 1.00 eq.) was dissolved in dry dimethylsulfoxid (max. 50 ppm H₂O) SeccoSolv® (31.250 ml; 0.440 mol; 7.04 eq.) at 100° C. A solution of potassium hydroxid (3.438 ml; 0.125 mol; 2.00 eq.) in dry ethanol (max. 20 ppm H₂O) SeccoSolv® (62.500 ml; 1.072 mol; 17.15 eq.) was added dropwise over a period of 10 minutes at 100° C. A white solid precipitated upon time. The suspension was stirred for another 30 min. The suspension was filtered at 100° C. and washed several times with dry ethanol and subsequently dried for 4 h in vacuum (10 mbar) at 100° C. The desired product, B (17.54 g; 60.0 mmol) was isolated as white solid in 95% yield.

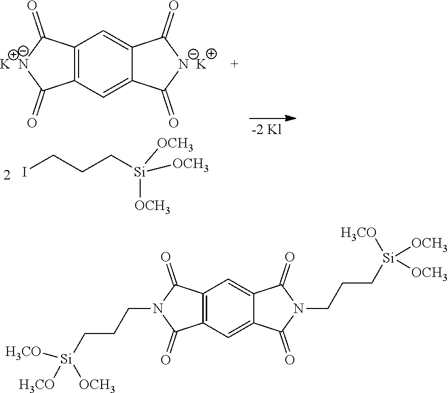

In a 250-mL round bottom three neck flask equipped with a reflux condenser pyrrolo[3,4-f]isoindole-2,6-diode-1,3,5,7-tetrone potassium (7.000 g; 24 mmol; 1.0 eq.) was dissolved in dimethylformamide (40.0 mL; 514 mmol; 21.5 eq.) and 3-iodopropyl(trimethoxy)silane (14.628 g; 48 mmol; 2.0 eq.) was added. The suspension was heated to 100° C. and stirred for 2 h at 100° C. The suspension was further heated (110° C.) followed by addition of more DMF (10 mL) and stirred for another 4 h until all material was dissolved. The solution was stirred at 110° C. for another 1 h and subsequently allowed to cool to RT. The solvent (DMF) was removed in vacuum (˜10 mbar) at 50° C. A yellow/orange suspension was isolated. This suspension was suspended in chloro-form (70 mL). The solid, probably KI, was filtered off and dried (7.41 g; 45 mmol, yield 93%). The solvent was removed in vacuum (˜10 mbar) at 50° C. The desired crude product, Pyromellitic bis[3-(trimethoxysilyl)propyl]imide (7.82 g; 14.5 mmol; 60.4%), was obtained as pale yellow solid material. The crude product can be purified by means of crystallization from methanol. After crystallization pure compound (6.18 g; 11.4 mmol; 47.5%) was obtained.

¹H-NMR (400.17 MHz, DMSO, 6 in ppm): 0.63 (m, 4H, Si—CH₂—); 1.69 (m, 4H, —CH₂—); 3.45 (s, 18H, O—CH₃); 3.6 (t, ³J_{HH}=7.1, 4H, N—CH₂—); 8.17 (s, 2H, CH).

¹³C-NMR (100.62 MHz, DMSO film, 6 in ppm): 6.37 (t, 2 CH₂); 21.73 (t, ¹J_{CH}=128.0 Hz, 2 CH₂); 24.26 (q, ¹J_{CH}=140.2 Hz, 2 CH₂); 50.46 (q, ¹J_{CH}=143.0 Hz, 6 CH₃); 117.41 (dt, ²J_{CH}=173.4 Hz, J=7.4 Hz, 2 CH); 137.46 (dd, J=14.9 Hz, ²J_{CH}=6.1 Hz, 4 C); 166.85 (q, J=˜3-4 Hz, 4 CO).

### DDSQ-T8Ph8 silsesquioxane

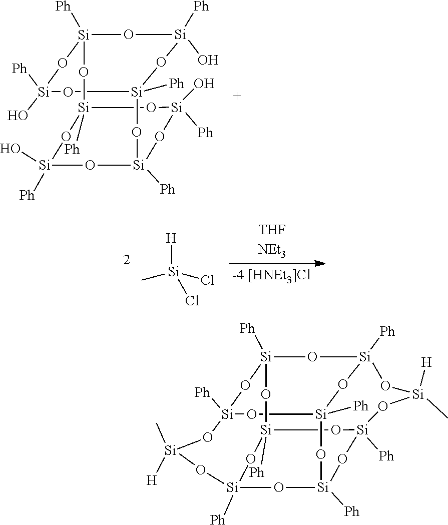

In a 1000-mL three-neck round bottom flask T8Ph8(OH)₄ (87.45 g; 81.77 mmol) was suspended in THE (850 mL). Triethylamine (41.14 g; 408.83 mmol) was added resulting in a clear solution. Dichloromethylsilane (94.06 g; 817.66 mmol) in was added within 45 min. An exothermic reaction was observed and a white solid precipitated. The suspension was stirred for 20 h at RT. Subsequently, the suspension was filtered and the isolated white crude product recrystallized from either hot (75° C.) toluene or a mixture of toluene and methanol. The desired product, DDSQ-T8Ph8(Si(CH₃)H)₂ (53.26 g; 46.16 mmol) was isolated as white solid in 56.5% yield.

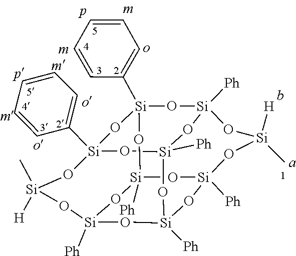 [SMILES: C[SiH]1O[Si]2(c3ccccc3)O[Si]3(c4ccccc4)O[Si]4(c5ccccc5)O[SiH](C)O[Si]5(c6ccccc6)O[Si](c6ccccc6)(O[Si](c6ccccc6)(O1)O[Si](c1ccccc1)(O5)O[Si](c1ccccc1)(O2)O4)O3]

¹H-NMR (400.17 MHz, CDCl₃, δ in ppm): 0.42 (d, ³J_{HH}=1.5 Hz, 6H^{a}_{cis and trans}), 5.03 (q, ³J_{HH}=1.5 Hz, 2H^{b}_{cis and trans}), 7.22 (tin, ³J_{HH}=7.6 Hz, 8H^{m′}_{cis and trans}), 7.30 (t, ³J_{HH}=7.6 Hz, 8H^{m}), 7.38 (tM, ³J_{HH}=7.6 Hz, 4H^{p′}_{cis and trans}), 7.44 (tt, ³J_{HH}=7.6 Hz, ⁴J_{HH}=1.4 Hz, 4H^{p}), 7.47 (dm, ³J_{HH}=8.0 Hz, 8H^{o}_{cis and trans}), 7.6 (dd, ³J_{HH}=8.0 Hz, ⁴J_{HH}=1.4 Hz, 8H^{o}). (^{o} overlaid)

¹³C-NMR (100.62 MHz, CDCl₃, δ in ppm): 0.9 (qd, ¹J_{CH}=119.5 Hz, ²J_{CH}=20.5 Hz, 2C¹_{cis and trans}), 127.9 (dm, ¹J_{CH}=159.8 Hz, 8C^{3′}_{cis and trans}), 128.0 (dd, ¹J_{CH}=159.8 Hz, ²J_{CH}=7.2 Hz, 8C³), 130.6 (dm, ¹J_{CH}=159.8 Hz, 4C^{5′}_{cis and trans}), 130.7 (dm, ¹J_{CH}=159.8 Hz, 4C⁵), 131.0 (m, 4C^{2′}_{cis and trans}), 131.8 (m, 4C²), 134.2 (dm, ¹J_{CH}=159.5 Hz, 8C⁴), 134.3 (dm, ¹J_{CH}=159.5 Hz,⁸C^{4′}_{cis and trans}).

²⁹Si-NMR (79.50 MHz, CDCl₃, δ in ppm): −32.82 (dq, ¹J_{SiH}=250.5 Hz, ²J_{SiH}=7.8 Hz, 2Si(H)CH_{3 trans}), −32.84 (dq, ¹J_{SiH}=250.5 Hz, ²J_{SiH}=7.8 Hz, 2Si(H)CH_{3 cis}), −77.8 (tm, ³J_{SiH}=6.3 Hz, 4 SiO_{1.5}), −79.3 (tm, ³J_{SiH}=6.3 Hz, 4 SiO_{1.5 cis and trans}).

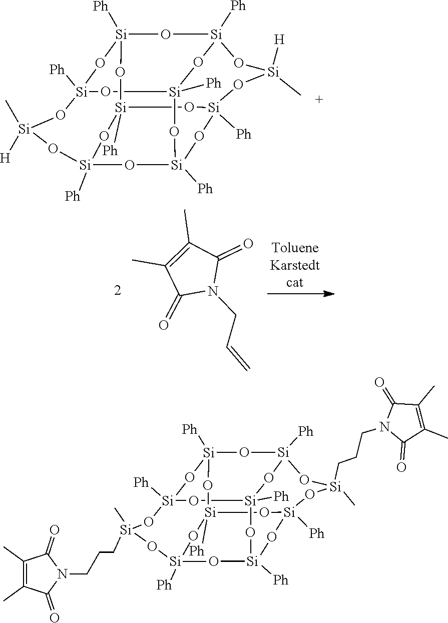

In a 1000-mL three-neck round bottom T8Ph8(Si(CH₃)H)₂ was dissolved in toluene (280 mL) at 60° C. A 2% Xylol solution of Karstedt catalyst and 1-Allyl-3,4-dimethyl-pyrrole-2,5-dione (6.01 g; 36.40 mmol) was added and stirred for 6 h at 60° C. and 18 h at RT. A white solid precipitated. Subsequently, the suspension was filtered and the isolated white crude product recrystallized from hot acetonitrile. The desired product (15.82 g; 10.66 mmol) was isolated as white solid in 88% yield.

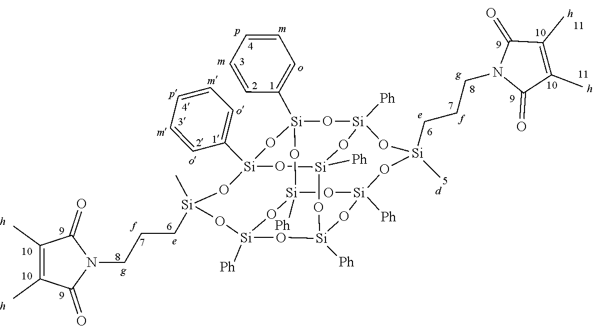

¹H-NMR (400.17 MHz, CDCl₃; δ in ppm): 0.28 (s, 6H_{d}), 0.66 (m, 4H^{e}), 1.62 (m, 4H^{f}), 1.93 (s, 12H^{h}), 3.40 (t, ³J_{HH}=7.3 Hz, 4H^{g}), 7.22 (t, ³J_{HH}=7.5 Hz, 8H^{m}), 7.26 (t, ³J_{HH}=8.2 Hz, 8H^{m′}), 7.36 (tt, ³J_{HH}=7.5 Hz, ³J_{HH}=1.4 Hz, 4H^{p}), 7.40 (tt, ³J_{HH}=7.5 Hz, ³J_{HH}=1.4 Hz, 4H^{p′}), 7.46 (d, ³J_{HH}=7.5 Hz, H^{o}), 7.54 (d, ³J_{HH}=7.5 Hz, H^{o′}).

¹³C{¹H}-NMR (100.65 MHz, CDCl₃; δ in ppm): −0.8 (C₅), 8.8 (C₁₁), 14.1 (C₆), 22.4 (C₇), 40.7 (C₈) 127.8 (C3), 127.9 (C3′), 130.5 (C4), 131.1 (C1), 132.1 (C1′), 134.1 (C2), 134.2 (C2′), 137.0 (C10), 172.3 (C9) ppm.

²⁹Si{¹H}-NMR (79.50 MHz, CDCl₃; δ in ppm): −18.1 (s, 2Si(H)CH₃), −78.5 (4 SiO_{1.5}), −79.5 (4 SiO_{1.5}).

FTIR (ATR) (v in cm⁻¹): 3050 (C—H aromat.), 2929 (C—H aliphat.), 1700 (C═O), 1594 and 1432 (C—C aromat.), 1084 (Si—C—Si).

### Synthesis of Siloxane Oligomers or Polymers

### Example 1—MPDMMIQ-453510

Methyltrimethoxysilane (2.72 g, 20.0 mmol), phenyltrimethoxysilane (3.17 g, 16.0 mmol), tetraethyl orthosilicate (0.83 g, 4.00 mmol), 3,4-dimethyl-1-(3-triethoxysilylpropyl)pyrrole-2,5-dione (1.46 g, 4.44 mmol) and propan-2-ol (14.0 g) were charged to the reaction vessel and purged with nitrogen. Tetramethylammonium hydroxide (3.66 g, 10.0 mmol, 25% in water) was added drop-wise to the reaction with rapid stirring over 5 minutes. The temperature was controlled to <25° C. during the addition. The reaction was stirred for 2 hours at 23° C. under nitrogen. The reaction mixture was poured into a rapidly stirred second flask containing deionized water (17.0 g), 35% hydrochloric acid (1.09 g, 10.5 mmol) and n-propyl acetate (17.0 g, 166 mmol). The mixture was stirred at 23° C. for 1 hour and then the aqueous phase was removed. The organic phase was washed with deionized water (17.0 g) then concentrated in vacuo to approximately 10 cm³ volume. Propylene glycol methyl ether acetate (20 g) was added to the organic phase and the solution concentrated in vacuo to give siloxane 1 (14.0 g, 32 wt.-% in propylene glycol methyl ether acetate, 98%). GPC (THF, 40° C.): Mₙ=1498 g/mol, M_{w}=2318 g/mol.

### Example 2—MPDMMIQ-403020

Methyltrimethoxysilane (1.63 g, 12.0 mmol), phenyltrimethoxysilane (1.90 g, 9.60 mmol), tetraethyl orthosilicate (0.50 g, 2.40 mmol), 3,4-dimethyl-1-(3-triethoxysilylpropyl)pyrrole-2,5-dione (1.98 g, 6.00 mmol) and propan-2-ol (8.39 g) were charged to the reaction vessel and purged with nitrogen. Tetramethylammonium hydroxide (2.20 g, 6.02 mmol, 25% in water) was added dropwise to the reaction with rapid stirring over 3 minutes. The temperature was controlled to <25° C. during the addition. The reaction was stirred for 2 hours at ambient temperature under nitrogen. The reaction mixture was poured into a rapidly stirred second flask containing deionized water (10.0 g), 35% hydrochloric acid (0.66 g, 6.30 mmol) and n-propyl acetate (10.2 g, 99.6 mmol). The mixture was stirred at ambient temperature for 1 hour then the aqueous phase was removed. The organic phase was washed with deionized water (10.0 g) then concentrated in vacuo to approximately 10 cm³ volume. Propylene glycol methyl ether acetate (20.0 g) was added to the organic phase and the solution was concentrated in vacuo to give siloxane 2 (12.0 g, 29 wt.-% in propylene glycol methyl ether acetate, 98%). GPC (THF, 40° C.): Mₙ=1550 g/mol, M_{w}=2352 g/mol.

### Example 3—MPDMMIQ-332730

Methyltrimethoxysilane (3.18 g, 23.4 mmol), phenyltrimethoxysilane (3.70 g, 18.7 mmol), tetraethyl orthosilicate (1.46 g, 7.00 mmol), 3,4-dimethyl-1-(3-triethoxysilylpropyl)pyrrole-2,5-dione (6.92 g, 21.0 mmol) and propan-2-ol (18.2 g) were charged to the reaction vessel and purged with nitrogen. Tetramethylammonium hydroxide (5.77 g, 15.8 mmol, 25% in water) was added dropwise to the reaction with rapid stirring over 3 minutes. The temperature was controlled to <25° C. during the addition. The reaction was stirred for 2 hours at ambient temperature under nitrogen. The reaction mixture was poured into a rapidly stirred second flask containing deionized water (23.8 g), 35% hydrochloric acid (1.81 g, 17.4 mmol) and n-propyl acetate (23.8 g, 233 mmol). The mixture was stirred at ambient temperature for 1 hour then the aqueous phase was removed. The organic phase was washed twice with deionized water (23.8 g) then concentrated in vacuo to approximately 15 cm³ volume. Propylene glycol methyl ether acetate (30.0 g) was added to the organic phase and the solution was concentrated again in vacuo to give siloxane 3 (15.3 g, 47 wt.-% in propylene glycol methyl ether acetate, yield 92%). GPC (THF, 40° C.): Mₙ=1718 g/mol, M_{w}=2727 g/mol.

### Example 4—MPDMMIQ-282240

Methyltrimethoxysilane (2.65 g, 19.4 mmol), phenyltrimethoxysilane (3.08 g, 15.6 mmol), tetraethyl orthosilicate (1.46 g, 7.00 mmol), 3,4-dimethyl-1-(3-triethoxysilylpropyl)pyrrole-2,5-dione (9.23 g, 28.0 mmol) and propan-2-ol (18.2 g) were charged to the reaction vessel and purged with nitrogen. Tetramethylammonium hydroxide (5.77 g, 15.8 mmol, 25% in water) was added dropwise to the reaction with rapid stirring over 3 minutes. The temperature was controlled to <25° C. during the addition. The reaction was stirred for 2 hours at ambient temperature under nitrogen. The reaction mixture was poured into a rapidly stirred second flask containing deionized water (23.8 g), 35% hydrochloric acid (1.81 g, 17.4 mmol) and n-propyl acetate (23.8 g, 233 mmol). The mixture was stirred at ambient temperature for 1 hour then the aqueous phase was removed. The organic phase was washed twice with deionized water (23.8 g) then concentrated in vacuo to approximately 15 cm³ volume. Propylene glycol methyl ether acetate (30.0 g) was added to the organic phase and the solution was concentrated again in vacuo to give siloxane 4 (16.9 g, 46 wt.-% in propylene glycol methyl ether acetate, yield 92%). GPC (THF, 40° C.): Mₙ=1753 g/mol, M_{w}=2609 g/mol.

### Example 5—MPDMMIQ-221850

Methyltrimethoxysilane (2.12 g; 15.6 mmol; 2.22 eq.), phenyltrimethoxysilane (2.47 g; 12.4 mmol; 1.78 eq.), tetraethyl orthosilicate (1.46 g; 7.00 mmol; 1.00 eq.), 3,4-dimethyl-1-(3-triethoxysilylpropyl)pyrrole-2,5-dione (11.53 g; 35.0 mmol; 5.00 eq.) and propan-2-ol (18.2 g; 0.30 mol; 43.3 eq.) were charged to the reaction vessel and purged with nitrogen. Tetramethyl-ammonium hydroxide 25% (5.77 g; 15.8 mmol; 2.26 eq.) was added drop-wise to the reaction with rapid stirring over 4 minutes. The temperature was controlled to <25° C. during the addition. The reaction was stirred for 2 hours at ambient temperature under nitrogen. The reaction mixture was poured into a rapidly stirred second flask containing deionized water (23.8 g), 35% hydrochloric acid (1.81 g; 17.4 mmol; 2.49 eq.) and n-propyl acetate (23.8 g; 233 mmol; 33.3 eq.). The mixture was stirred at ambient temperature for 40 minutes then the aqueous phase was removed. The organic phase was washed twice with deionized water (23.8 g) then concentrated in vacuo to approximately 15 mL volume. PGMEA (40.0 g) was added to the organic phase and the solution was concentrated again in vacuo to give a siloxane 5 (30.5 g, 34.3 wt.-% in propylene glycol methyl ether acetate, yield: 97.5%) GPC (TH F, 40° C.): Mₙ 1464, M_{w} 1795, PDI 1.23.

### Example 6—MDMMIQ-4050

Methyltrimethoxysilane (1.64 g; 12.0 mmol; 1.00 eq.), tetraethyl orthosilicate (0.63 g; 3.0 mmol; 0.25 eq.), 3,4-dimethyl-1-(3-triethoxysilylpropyl)pyrrole-2,5-dione (4.94 g; 15.0 mmol; 1.25 eq.) and propan-2-ol (7.8 g; 130 mmol; 11 eq.) were charged to the reaction vessel and purged with nitrogen. Tetramethylammonium hydroxide 25% (2.47 g; 6.78 mmol; 0.565 eq.) was added drop-wise to the reaction with rapid stirring over 5 minutes. The temperature was controlled to <25° C. during the addition. The reaction was stirred for 2 hours at ambient temperature under nitrogen. The reaction mixture was poured into a rapidly stirred second flask containing deionized water (10.0 g), 35% hydrochloric acid (0.74 g; 7.1 mmol; 0.59 eq.) and n-propyl acetate (10.2 g; 99.9 mmol; 8.32 eq.). The mixture was stirred at ambient temperature for 1 hour then the aqueous phase was removed. The organic phase was washed with deionized water (10.0 g) then concentrated in vacuo to approximately 10 mL volume. PGMEA (20.0 g) was added to the organic phase and the solution was concentrated again in vacuo to give siloxane 6 (14.2 g, 27.0 wt.-% in propylene glycol methyl ether acetate, yield: 90.0%), GPC (THF, 40° C.): Mₙ 1511, M_{w} 2219, PDI 1.47.

### Example 7—MADMMIQ-502020

### Example 7.1—MADMMIQ 502020

In a 1000-mL three-neck round bottom flask methyltrimethoxysilane (38.70 g; 281.3 mmol; 1 eq.), 3,4-dimethyl-1-(3-triethoxysilylpropyl)pyrrole-2,5-dione (37.82 g; 112.5 mmol; 0.40 eq.), Trimethoxy(octyl)silane (26.37 g; 112.5 mmol; 0.40 eq.) and tetraethoxysilane (11.84 g; 56.3 mmol; 0.20 eq.) are dissolved in 2-propanol (186 mL; 2433 mmol) and cooled with ice (5° C.) in an argon atmosphere (X1). The condensation reaction was started adding tetramethylammonium hydroxide solution (25% in water; 46.35 g; 127.1 mmol; 0,45 eq.) within five minutes. The exothermic reaction has to be controlled so that the reaction mixtures temperature does not exceed 25° C. The clear and colorless solution was allowed to warm to RT and stirred for two hours (magnetic stirrer 400 rpm). In another 1000-mL round bottom flask an emulsion (X2) of de-ionized water (191.25 g), hydrochloric acid (15.20 g; 133.43 mmol; 0.47 eq.), n-propyl acetate (191.25 g; 1872.6 mmol; 6.66 eq.) (bi-phasic system) was prepared to quench the reaction. The solution X1 was added to X2 yielding a bi-phasic system. The white turbulent emulsion was stirred for 1 h until both phases were separated. The oligomer dissolved in the upper organic phase was washed three times with de-ionized water (pH 4-5). Propylene glycol monomethyl ether acetate (225.0 g) was added to the solution and finally the oligomer solution concentrated in vacuum (˜10 mbar) at 50° C. to ca. 20-45 wt.-% solid content. Any solid precipitation can be removed by filtration. The clear and colorless solution can be used for further reactions.

GPC (THF, Int. Standard: toluene, 40° C.); Mₙ=2245 g/mol; M_{w}=5157 g/mol; M_{z}=11652 g/mol, PDI=2.30.

Free-standing films were prepared by filling a silicon mold (moldstar) with the MADMMIQ502020 solution (40% in PGMEA) and cured using the following procedure:

### Curing Conditions:

10 min at 90° C.

68 min UV (365 nm; 10 J/cm²)

90° C.-120° C. (3 K/min)

20 min at 120° C.

120° C.-175° C. (3.6 K/min)

30 min at 175° C.

### Measurements:

Film thickness: 410 μm

TGA: 386° C. (47% loss)

CTE: 209 ppm/K (below T_{g})|299 ppm/K (above T_{g})

T_{g}: 30.08° C.

E2B: 9.71%

Fₘₐₓ=5.85 MPa.

Free-standing films were prepared by filling a silicon mold (moldstar) with a mixture of MADMMIQ502020 solution (40% in PGMEA→3.6 g (solid content); −28.8 mmol) and Priamin-DMMI2 (1.8 g; −2.3 mmol).

### Curing Conditions:

10 min at 90° C.

68 min UV (365 nm; 10 J/cm²)

90° C.-120° C. (3 K/min)

20 min at 120° C.

120° C.-175° C. (3.6 K/min)

30 min at 175° C.

### Measurements:

Film thickness: 362 μm

TGA: 466.7° C. (60% loss)

E2B: 19.9%

Fₘₐₓ=0.99 MPa.

### Example 7.2—MADMMIQ-502020

Methyltrimethoxysilane (4.087 g; 30.00 mmol; 1.000 eq.), tetraethyl orthosilicate (1.250 g; 6.00 mmol; 0.200 eq.),trimethoxy(octyl)silane (2.813 g; 12.00 mmol; 0.400 eq.), 3,4-dimethyl-1-(3-triethoxysilylpropyl)pyrrole-2,5-dione (3.954 g; 12.00 mmol; 0.400 eq.) and propan-2-ol (14.600 g; 242.95 mmol; 8.098 eq.) were charged to the reaction vessel and purged with nitrogen. Tetramethylammonium hydroxide 25% (4.944 g; 13.56 mmol; 0.452 eq.) was added drop-wise to the reaction with rapid stirring over 4 minutes. The temperature was controlled to <25° C. during the addition. The reaction was stirred for 2 hours at ambient temperature under nitrogen. The reaction mixture was poured into a rapidly stirred second flask containing deionized water (20.00 g), 35% hydrochloric acid (1.481 g; 14.22 mmol; 0.474 eq.) and n-propyl acetate (20.000 g; 195.83 mmol; 6.528 eq.). The mixture was stirred at ambient temperature for 1 hour then the aqueous phase was removed. The organic phase was washed twice with deionized water (20.0 g) then concentrated in vacuo to approximately 15 mL volume. PGMEA (25.0 g) was added to the organic phase and the solution was concentrated again in vacuo to give siloxane 7.2 (20.5 g, 33.1 wt.-% in propylene glycol methyl ether acetate, yield: 96.8%), GPC (THF, 40° C.): Mₙ 1910, M_{w} 3054, PDI 1.60.

### Example 8—MPDMMI-483220

Methyltrimethoxysilane (1.64 g; 12.0 mmol; 1.00 eq.), phenyltrimethoxysilane (1.59 g; 8.00 mmol; 0.667 eq.), 3,4-dimethyl-1-(3-triethoxysilylpropyl)pyrrole-2,5-dione (1.65 g; 5.00 mmol; 0.417 eq.) and propan-2-ol (6.00 g; 99.8 mmol; 8.32 eq.) were charged to the reaction vessel and purged with nitrogen. Tetramethylammonium hydroxide (2.06 g; 5.65 mmol; 0.471 eq.) was added drop-wise to the reaction with rapid stirring over 3 minutes. The temperature was controlled to <25° C. during the addition. The reaction was stirred for 4 hours at ambient temperature under nitrogen. The reaction mixture was poured into a rapidly stirred second flask containing deionized water (8.0 g), 35% hydrochloric acid (0.619 g; 5.94 mmol; 0.495 eq.), and n-propyl acetate (8.0 g; 78. mmol; 6.5 eq.). The mixture was stirred at ambient temperature for 1 hour then the aqueous phase was removed. The organic phase was washed with deionized water (8.0 g) then concentrated in vacuo to approximately 10 mL volume. PGMEA (20.0 g) was added to the organic phase and the solution was concentrated again in vacuo to give siloxane 8 (9.7 g, 27.9 wt.-% in propylene glycol methyl ether acetate, yield: 92.8%), GPC (THF, 40° C.): Mₙ 1193, M_{w} 1553, PDI 1.30.

### Example 9—MDMMIQ-56204

Methyltrimethoxysilane (1.91 g; 14.0 mmol; 1.00 eq.), tetraethyl orthosilicate (1.25 g; 6.0 mmol; 0.429 eq.), 3,4-dimethyl-1-(3-triethoxysilylpropyl)pyrrole-2,5-dione (1.65 g; 5.00 mmol; 0.357 eq.) and PGME (6.00 g; 66.6 mmol; 4.76 eq.) were charged to the reaction vessel and purged with nitrogen. Choline hydroxide 50% (2.399 g; 9.90 mmol; 0.707 eq.) was added drop-wise to the reaction with rapid stirring over 4 minutes. The temperature was controlled to <25° C. during the addition. The reaction was stirred for 1 hour at ambient temperature under nitrogen. The reaction mixture was poured into a rapidly stirred second flask containing deionized water (8.0 g), citric acid (1.99 g; 10.4 mmol; 0.740 eq.), and n-propyl acetate (8.00 g; 78.3 mmol; 5.60 eq.). The mixture was stirred at ambient temperature for 1 hour then the aqueous phase was removed. The organic phase was washed with deionized water (8.0 g) then concentrated in vacuo to approximately 10 mL volume. PGME (20.0 g) was added to the organic phase and the solution was concentrated again in vacuo to give siloxane 9 (7.9 g, 26.0 wt.-% in propylene glycol methyl ether acetate, yield: 85.9%), GPC (THF, 40° C.): Mₙ 1345, M_{w} 1839, PDI 1.37.

### Example 10—MPDMMI-502525

Methyltrimethoxysilane (1.36 g; 10.00 mmol; 1.00 eq.), phenyltrimethoxy-silane (0.99 g; 5.00 mmol; 0.50 eq.), 3,4-dimethyl-1-(3-triethoxysilyl-propyl)pyrrole-2,5-dione (1.37 g; 5.00 mmol; 0.50 eq.) and PGMEA (6.08 g; 46.00 mmol; 4.60 eq.) were charged to the reaction vessel and purged with nitrogen. Sodium hydroxide (0.60 g; 15.00 mmol; 1.50 eq.) was dissolved in water (1.44 g; 80.00 mmol; 8.00 eq.) and was added to the vessel in one portion then the reaction stirred for 1 h at ambient temperature under nitrogen. The reaction mixture was poured into a rapidly stirred second flask containing deionized water (6.0 g), hydrochloric acid (1.64 g; 15.75 mmol; 1.58 eq.), and n-propyl acetate (6.08 g; 59.50 mmol; 5.95 eq.). The mixture was stirred at ambient temperature for 1 hour then the aqueous phase was removed. The organic phase was washed with three times deionized water (6.0 g) then concentrated in vacuo to approximately 5 mL volume. PGMEA (20.0 g) was added to the organic phase and the solution was concentrated again in vacuo to give siloxane 10 (4.5 g, 28.2 wt.-% in propylene glycol methyl ether acetate, yield: 54%), GPC (THF, 40° C.): Mₙ 974, M_{w} 1203, PDI 1.24.

### Example 11—MDMMIQ-6525

Methyltrimethoxysilane (2.724 g; 20.00 mmol; 1.000 eq.), tetraethyl orthosilicate (0.642 g; 3.08 mmol; 0.15 eq.),3,4-dimethyl-1-(3-triethoxysilylpropyl)pyrrole-2,5-dione (2.537 g; 7.70 mmol; 0.38 eq.) and propan-2-ol (7.993 g; 0.13 mol; 6.65 eq.) were charged to the reaction vessel and purged with nitrogen. Tetramethylammonium hydroxide 25% (2.534 g; 6.95 mmol; 0.35 eq.) was added drop-wise to the reaction with rapid stirring over 4 minutes. The temperature was controlled to <25° C. during the addition. The reaction was stirred for 2 hours at ambient temperature under nitrogen. The reaction mixture was poured into a rapidly stirred second flask containing deionized water (10.00 g), 35% hydrochloric acid (0.760 g; 7.30 mmol; 0.365 eq.) and n-propyl acetate (10.213 g; 100.00 mmol; 5.000 eq.). The mixture was stirred at ambient temperature for 1 hour then the aqueous phase was removed. The organic phase was washed three times with deionized water (10.0 g) then concentrated in vacuo to approximately 1.5 mL volume. PGMEA (12.0 g) was added to the organic phase and the solution was concentrated again in vacuo to give siloxane 11(3.3 g, 13.9 wt.-% in propylene glycol methyl ether acetate, yield: 11.6%), GPC (THF, 40° C.): Mₙ 1108, M_{w} 1635, PDI 1.48.

### Example 12—MDMMIQ-7020

Methyltrimethoxysilane (34.328 g; 252.00 mmol; 1.000 eq.), tetraethyl orthosilicate (7.502 g; 36.01 mmol; 0.143 eq.), 3,4-dimethyl-1-(3-triethoxysilylpropyl)pyrrole-2,5-dione (23.720 g; 72.00 mmol; 0.286 eq.) and propan-2-ol (93.600 g; 1557.53 mmol; 6.181 eq.) were charged to the reaction vessel and purged with nitrogen. Tetramethylammonium hydroxide 25% (29.665 g; 81.36 mmol; 0.323 eq.) was added drop-wise to the reaction with rapid stirring over 5 minutes. The temperature was controlled to <25° C. during the addition. The reaction was stirred for 2 hours at ambient temperature under nitrogen. The reaction mixture was poured into a rapidly stirred second flask containing deionized water (122.00 g), 35% hydrochloric acid (8.900 g; 85.43 mmol; 0.339 eq.), and n-propyl acetate (122.400 g; 1198.45 mmol; 4.756 eq.). The mixture was stirred at ambient temperature for 1 hour then the aqueous phase was removed. The organic phase was washed with deionized water (122.0 g) then concentrated in vacuo to approximately 100 mL volume. PGMEA (72.0 g) was added to the organic phase and the solution was concentrated again in vacuo to give siloxane 12 (85.4 g, 39.9 wt.-% in propylene glycol methyl ether acetate, yield: 97.6%), GPC (THF, 40° C.): Mₙ 1498, M_{w} 2322, PDI 1.55.

### Example 13—MPVDMMIQ-28222020

Methyltrimethoxysilane (2.838 g; 20.83 mmol; 1.39 eq.), phenyltrimethoxy-silane (3.305 g; 16.67 mmol; 1.111 eq.), tetraethyl orthosilicate (1.562 g; 7.50 mmol; 0.50 eq.), vinyltrimethoxysilane (2.223, 15.00 mmol, 1.00 eq.), 3,4-dimethyl-1-(3-triethoxysilylpropyl)pyrrole-2,5-dione (4.942 g; 15.00 mmol; 1.00 eq.) and propan-2-ol (19.000 g; 316.17 mmol; 21.08 eq.) were charged to the reaction vessel and purged with nitrogen. Tetramethylammonium hydroxide 25% (6.180 g; 16.95 mmol; 1.130 eq.) was added drop-wise to the reaction with rapid stirring over 5 minutes. The temperature was controlled to <25° C. during the addition. The reaction was stirred for 2 hours at ambient temperature under nitrogen. The reaction mixture was poured into a rapidly stirred second flask containing deionized water (25.00 g), 35% hydrochloric acid (1.855 g; 17.81 mmol; 1.187 eq.), and n-propyl acetate (25.000 g; 244.78 mmol; 16.319 eq.). The mixture was stirred at ambient temperature for 1 hour then the aqueous phase was removed. The organic phase was washed with deionized water (25.0 g) then concentrated in vacuo to approximately 15 mL volume. PGMEA (30.0 g) was added to the organic phase and the solution was concentrated again in vacuo to give siloxane 13 (22.4 g, 31.8 wt.-% in propylene glycol methyl ether acetate, yield: 96.6%), GPC (THF, 40° C.): Mₙ 1275, M_{w} 1586, PDI 1.24.

### Example 14—MDMMI-5050

Methyltrimethoxysilane (2.724 g; 20.00 mmol; 1.000 eq.), 3,4-dimethyl-1-(3-triethoxysilylpropyl)pyrrole-2,5-dione (6.589 g; 20.00 mmol; 1.000 eq.) and propan-2-ol (10.500 g; 174.72 mmol; 8.736 eq.) were charged to the reaction vessel and purged with nitrogen. Tetramethylammonium hydroxide 25% (3.296 g; 9.04 mmol; 0.452 eq.) was added drop-wise to the reaction with rapid stirring over 3 minutes. The temperature was controlled to <25° C. during the addition. The reaction was stirred for 2 hours at ambient temperature under nitrogen. The reaction mixture was poured into a rapidly stirred second flask containing deionized water (13.00 g), 35% hydrochloric acid (0.983 g; 9.44 mmol; 0.472 eq.), and n-propyl acetate (13.000 g; 127.29 mmol; 6.364 eq.). The mixture was stirred at ambient temperature for 1 hour then the aqueous phase was removed. The organic phase was washed three times with deionized water (13.0 g) then concentrated in vacuo to approximately 15 mL volume. PGMEA (20.0 g) was added to the organic phase and the solution was concentrated again in vacuo to give siloxane 14 (16.6 g, 30.4 wt.-% in propylene glycol methyl ether acetate, yield: 99.0%), GPC (THF, 40° C.): Mₙ 1454, M_{w} 1909, PDI 1.31.

### Example 15—MFDMMIQ-202050

Methyltrimethoxysilane (1.362 g; 10.00 mmol; 1.000 eq.), tetraethyl orthosilicate (1.042 g; 5.00 mmol; 0.500 eq.), 3,4-dimethyl-1-(3-triethoxysilylpropyl)pyrrole-2,5-dione (8.237 g; 25.00 mmol; 2.500 eq.), trimethoxy(3,3,4,4,5,5,6,6,6-nonafluorohexyl)silane (3.683 g; 10.00 mmol; 1.000 eq.) and propan-2-ol (13.000 g; 216.32 mmol; 21.632 eq.) were charged to the reaction vessel and purged with nitrogen. Tetramethyl-ammonium hydroxide 25% (4.120 g; 11.30 mmol; 1.130 eq.) was added drop-wise to the reaction with rapid stirring over 2 minutes. The temperature was controlled to <25° C. during the addition. The reaction was stirred for 3.5 hours at ambient temperature under nitrogen. The reaction mixture was poured into a rapidly stirred second flask containing deionized water (17.00 g), 35% hydrochloric acid (1.240 g; 11.90 mmol; 1.190 eq.), and n-propyl acetate (17.000 g; 166.45 mmol; 16.645 eq.). The mixture was stirred at ambient temperature for 1 hour then the aqueous phase was removed. The organic phase was washed twice with deionized water (17.0 g) then concentrated in vacuo to approximately 10 mL volume. PGMEA (22.0 g) was added to the organic phase and the solution was concentrated again in vacuo to give siloxane 15 (30.4 g, 29.0 wt.-% in propylene glycol methyl ether acetate, yield: 93.6%), GPC (THF, 40° C.): Mₙ 1382, M_{w} 1814, PDI 1.26.

### Example 16—MDMMIQ-2070

Methyltrimethoxysilane (1.090 g; 8.00 mmol; 1.000 eq.), tetraethyl orthosilicate (0.833 g; 4.00 mmol; 0.500 eq.), 3,4-dimethyl-1-(3-triethoxysilylpropyl)pyrrole-2,5-dione (9.225 g; 28.00 mmol; 3.500 eq.) and propan-2-ol (10.400 g; 173.06 mmol; 21.632 eq.) were charged to the reaction vessel and purged with nitrogen. Tetramethylammonium hydroxide 25% (3.296 g; 9.04 mmol; 1.130 eq.) was added drop-wise to the reaction with rapid stirring over 2 minutes. The temperature was controlled to <25° C. during the addition. The reaction was stirred for 3.5 hours at ambient temperature under nitrogen. The reaction mixture was poured into a rapidly stirred second flask containing deionized water (13.60 g), 35% hydrochloric acid (0.938 g; 9.52 mmol; 1.190 eq.), and n-propyl acetate (13.600 g; 133.16 mmol; 16.645 eq.). The mixture was stirred at ambient temperature for 1 hour then the aqueous phase was removed. The organic phase was washed with deionized water (13.0 g) then concentrated in vacuo to approximately 15 mL volume. PGMEA (40.0 g) was added to the organic phase and the solution was concentrated again in vacuo to give siloxane 16 (23.0 g, 27.0 wt.-% in propylene glycol methyl ether acetate, yield: 90.0%), GPC (THF, 40° C.): Mₙ 1254, M_{w} 1583, PDI 1.23.

### Example 17—DMMI-100

3,4-dimethyl-1-(3-triethoxysilylpropyl)pyrrole-2,5-dione (2.88 g; 8.75 mmol; 1.00 eq.) and propan-2-ol (5.00 g; 83.2 mmol; 9.51 eq.) were charged to the reaction vessel and purged with nitrogen. Tetramethylammonium hydroxide 25% (0.72 g; 1.98 mmol; 0.23 eq.) was added drop-wise to the reaction with rapid stirring over 2 minutes. The temperature was controlled to <25° C. during the addition. The reaction was stirred for 3.5 hours at ambient temperature under nitrogen. The reaction mixture was poured into a rapidly stirred second flask containing deionized water (15.0 g), 35% hydrochloric acid (0.22 g; 2.08 mmol; 0.24 eq.), and n-propyl acetate (15.0 g; 147 mmol; 16.8 eq.). The mixture was stirred at ambient temperature for 1 hour then the aqueous phase was removed. The organic phase was washed twice with deionized water (13.0 g) then concentrated in vacuo to approximately 5 mL volume. Yield: 90%, GPC (THF, 40° C.): Mₙ 1723, M_{w} 2029, PDI 1.18.

### Photopatterning

### Negative Type|UV|No Initiator

Substrates (glass or Si wafer) were washed as per a standard process of sequential ultra-sonication in acetone and isopropyl alcohol for 10 minutes each. The oligomer or polymer solution (20-40% total solid content) was spin coated at a rate of 1000-2000 rpm to yield a uniform film with a target thickness of 1-3 μm. Residual solvent was removed by annealing between 90 and 110° C. for 2 minutes.

The coated substrate was UV irradiated (λ=254 nm, 2-10 J/cm² dose) through a mask. Following UV irradiation, the sample was wiped gently with a lint-free cloth soaked in a solubilizing solvent such as propylene glycol monomethyl ether acetate (PGMEA) to remove uncured oligomer or polymer residue and reveal a pattern consisting of crosslinked material.

Following UV crosslinking, the oligomer or polymer film may undergo an additional thermal bake step at 230° C. for 60 min to crosslink any thermally active groups.

### Example 18—Photopatterning Example 7 (MADMMIQ-502020)

UV cure, 8 J/cm² 254 nm, UV lamp power 3 mW/cm² through a simple shadow mask pattern. The irradiated film was wiped with a PGMEA soaked lint free cloth to remove uncured region and reveal pattern.

Substrates (glass or Si wafer) were washed as per a standard process of sequential ultra-sonication in acetone and isopropyl alcohol for 10 minutes each. The oligomer solution (20-40% total solid content) with 2 phr (based on solid content of oligomer) Omnipol TX was spin coated at a rate of 1000-2000 rpm to yield a uniform film with a target thickness of 1-3 μm. Residual solvent was removed by annealing between 90 and 110° C. for 2 minutes. The oligomer coated substrate was UV irradiated (λ=365 nm, 2-10 J/cm² dose) through a mask. Following UV irradiation, the sample was wiped gently with a lint-free cloth soaked in a solubilizing solvent such as propylene glycol monomethyl ether acetate (PGMEA) to remove uncured oligomer residue and reveal a pattern consisting of crosslinked material. Following UV crosslinking the oligomer film may undergo an additional thermal bake step at 230° C. for 60 min to crosslink any thermally active groups.

### Example 19—Photopatterning & Film Retention Measurements

Substrates (glass or Si wafer) were washed as per a standard process of sequential ultra-sonication in acetone and isopropyl alcohol for 10 minutes each. The oligomer solution (20-40% total solid content) with optionally 0-2 phr (based on solid content of oligomer) Omnipol TX or Speedcure 7010 was spin coated at a rate of 1000-2000 rpm to yield a uniform film. Residual solvent was removed by annealing between 90 and 110° C. for 2 minutes. The oligomer coated substrate was UV irradiated (λ=254 nm, 1-10 J/cm² dose, see Table 1) (λ=365 nm, 1-10 J/cm² dose, see Table 2). The film thickness was determined by measuring the step height of a scratch made through the film using stylus profilometry.

A layer of solubilizing solvent such as propylene glycol monomethyl ether acetate (PGMEA) was dispensed onto the polymer coated substrate and allowed to soak for 1 minute before spinning dry with an option anneal at 80-120° C. for 1-2 minutes. The film thickness was determined by measuring the step height of a scratch made through the residual film using stylus profilometry. The percentage of film retained following solvent exposure was calculated.

TABLE 1
Comparison of percentage film retention for polymers exposed to
254 nm UV.

| | | Photosensitizer | | Percentage |
|---|---|---|---|---|
| | | concentration | 365 nm | film retention |
| | | (phr based on | UV cure | following |
| | | oligomer solid | dose | 1-minute |
| Oligomer | Photosensitizer | content) | (J/cm²) | PGMEA soak |
| 5 | — | 0 | 1 | 90 |
| 5 | — | 0 | 2 | 92 |
| 5 | — | 0 | 4 | 95 |
| 5 | Omnipol TX | 2 | 1 | 98 |
| 5 | Omnipol TX | 2 | 2 | 96 |
| 5 | Omnipol TX | 2 | 4 | 99 |
| 6 | — | 0 | 1 | 97 |
| 6 | — | 0 | 2 | 98 |
| 6 | — | 0 | 4 | 99 |
| 6 | Omnipol TX | 2 | 1 | 97 |
| 6 | Omnipol TX | 2 | 2 | 98 |
| 6 | Omnipol TX | 2 | 4 | 99 |
| 4 | — | 0 | 4 | 98 |
| 4 | — | 0 | 6 | >99 |
| 3 | — | 0 | 4 | 98 |
| 3 | — | 0 | 6 | 99 |

TABLE 2
Comparison of percentage film retention for polymers exposed to
365 nm UV.

| | | Photosensitizer | | Percentage |
|---|---|---|---|---|
| | | concentration | 365 nm | film retention |
| | | (phr based on | UV cure | following |
| | | oligomer solid | dose | 1-minute |
| Oligomer | Photosensitizer | content) | (J/cm²) | PGMEA soak |
| 6 | Omnipol TX | 2 | 0 | 0 |
| 6 | Speedcure 7010 | 2 | 0 | 0 |
| 6 | Omnipol TX | 1 | 2 | >99 |
| 6 | Omnipol TX | 2 | 2 | 98 |
| 6 | Speedcure 7010 | 2 | 2 | >99 |
| 6 | Omnipol TX | 2 | 4 | 95 |
| 6 | Speedcure 7010 | 2 | 4 | >99 |
| 6 | Omnipol TX | 2 | 6 | >99 |
| 6 | Speedcure 7010 | 2 | 6 | >99 |
| 12 | Omnipol TX | 2 | 0 | 0 |
| 12 | Omnipol TX | 2 | 6 | 51 |
| 12 | Speedcure 7010 | 2 | 6 | 34 |
| 12 | Omnipol TX | 5 | 6 | 67 |

### Example 20—Real Relative Permittivity Measurements of Dielectric Films

ITO glass was sequentially washed in acetone and isopropyl alcohol. The oligomer of interest was then spin coated from solution (20-40% solid content) at a rate of 1000-2000 rpm to yield a uniform film with a thickness of 500-2000 nm. Residual solvent was removed by annealing between 90 and 100° C. for 2 minutes. Optionally, the film may then undergo UV cure (λ=254 nm, 2 J/cm² dose) or thermal cure (165° C., 30 minutes) to crosslink reactive groups within the film.

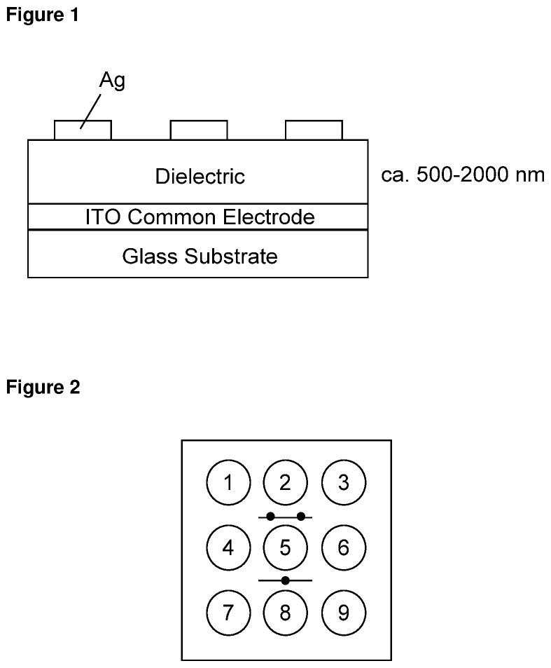

Electrodes (60 nm, Ag) were deposited by evaporation through a shadow mask with circular apertures to produce a pattern of 9 circular electrodes per 1-inch substrate as per FIGS. 1 and 2.

Film capacitance was measured as a function of frequency (21 Hz-1000 Hz) using a precision LCR meter (Keysight, E4980AL). The film thickness was measured using a stylus profilometer (KLA-tencor D-500) at three different locations. The relative permittivity of the polymer was then calculated from the following relationship,

$$C = {ɛ}_{r} {ɛ}_{0} \frac{A}{d}$$

where C is the measured capacitance, εᵣ is the real relative permittivity of the polymer, ε₀ is the permittivity of free space, A is the surface area of each electrode and d is the average film thickness.

Specific examples of permittivity following thermal cure are given below. Permittivity values shown were measured at 1000 Hz and are the average values of three data points (see Table 3).

TABLE 3
Permittivity of cured polymers

| | Permittivity at 1000 Hz | | |
|---|---|---|---|
| | No thermal or | | |
| Polymer | UV cure | UV cure | Thermal cure |
| 7.2 | — | 3.2 | 3.1 |
| 6 | 3.3 | 3.7 | 3.2 |
| 5 | 3.5 | 3.7 | — |

1. A monomer composition for the preparation of a siloxane oligomer or polymer, comprising:
(a) a first siloxane monomer; and
(b) a second siloxane monomer;
wherein the first siloxane monomer comprises a substituted or unsubstituted maleimide group.

2. The monomer composition according to claim 1,
wherein the first siloxane monomer is represented by Formula (1): 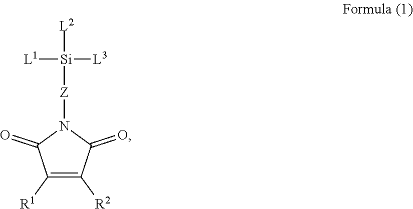
wherein:
L¹, L² and L³ are the same or different from each other and each independently is selected from R, OR, and halogen, wherein at least one of L¹, L² and L³ is OR or halogen;
R is selected from the group consisting of H, straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡C—, and wherein one or more H atoms are optionally replaced by F;
R¹ and R² are the same or different from each other and each independently is selected from H, alkyl having 1 to 20 carbon atoms, cycloalkyl having 3 to 20 carbon atoms and aryl having 6 to 20 carbon atoms, wherein one or more H atoms are optionally replaced by F, or R¹ and R² together form a mono- or polycyclic organic ring system, wherein one or more H atoms are optionally replaced by F;
Z denotes a straight-chain alkylene group having 1 to 20 carbon atoms, a branched-chain alkylene group having 3 to 20 carbon atoms or a cyclic alkylene group having 3 to 20 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡C—, and in which one or more H atoms are optionally replaced by F;
Y¹ and Y² are the same or different from each other and each independently is selected from H, F, Cl and CN;
R⁰ and R⁰⁰ are the same or different from each other and each independently is selected from H, straight-chain alkyl having 1 to 20 carbon atoms and branched-chain alkyl having 3 to 20 carbon atoms, which are optionally fluorinated; and
wherein the second siloxane monomer is different from the first siloxane monomer.

3. The monomer composition according to claim 2, wherein one of the conditions (1) or (2) applies:
L¹=L²=L³=OR; or (1)
L¹=L²=R, and L³=Cl. (2)

4. The monomer composition according to claim 2,
wherein R¹ and R² are the same or different from each other and each independently is selected from H, alkyl having 1 to 12 carbon atoms, cycloalkyl having 3 to 12 carbon atoms and aryl having 6 to 14 carbon atoms, wherein one or more H atoms are optionally replaced by F, or R¹ and R² together form a mono- or polycyclic aliphatic ring system, a mono- or polycyclic aromatic ring system or a polycyclic aliphatic and aromatic ring system, wherein one or more H atoms are optionally replaced by F.

5. The monomer composition according to claim 1, wherein the second siloxane monomer is represented by one of the following Structures S1 to S5: 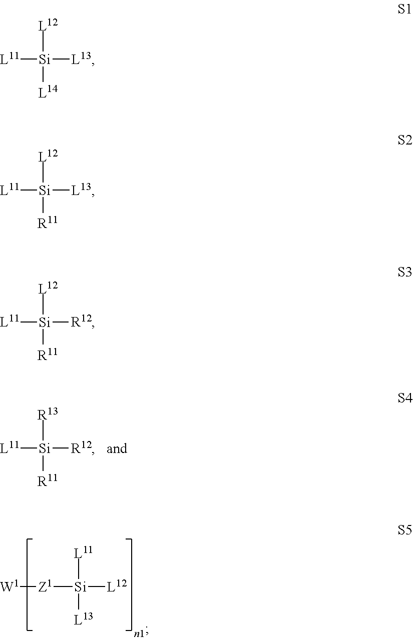
wherein:
L¹¹, L¹², L¹³, and L¹⁴ are the same or different from each other and each independently is selected from OR′ and halogen;
R′ is selected from the group consisting of straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡C—, and wherein one or more H atoms are optionally replaced by F;
R¹¹, R¹² and R¹³ are the same or different from each other and each independently is selected from the group consisting of H, straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, which optionally contain one or more functional groups selected from —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CR⁰═CR⁰⁰₂—, —CY¹═CY²—, and —C═C—, and wherein one or more H atoms are optionally replaced by F;
Z′ denotes a straight-chain alkylene group having 1 to 20 carbon atoms, a branched-chain alkylene group having 3 to 20 carbon atoms or a cyclic alkylene group having 3 to 20 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C═C—, and in which one or more H atoms are optionally replaced by F;
W¹ denotes a divalent, trivalent or tetravalent organic moiety;
R⁰, R⁰⁰, Y¹, and Y² are defined as in claim 1; and
n1=2, 3 or 4.

6. The monomer composition according to claim 5,
wherein W¹ is represented by one of the following Structures W1 to W4: 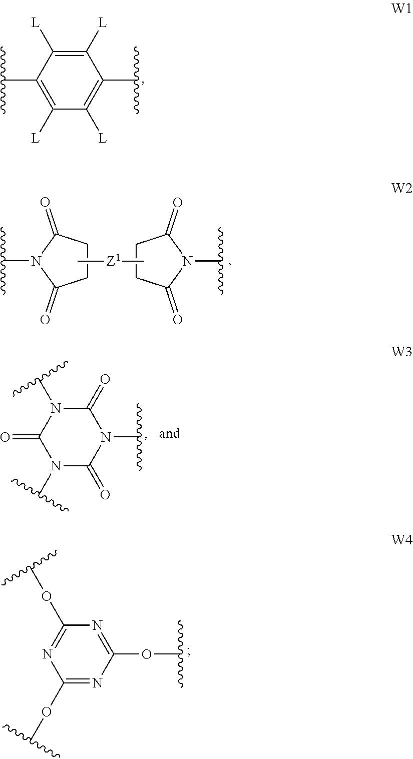
wherein:
L is selected from H, —F, —Cl, —NO₂, —CN, —NC, —NCO, —NCS, —OCN, —SCN, —OH, —R⁰, —OR⁰, —SR⁰, —C(═O)R⁰, —C(═O)—OR⁰, —O—C(═O)—R⁰, —NH₂, —NHR⁰, —NR⁰R⁰⁰, —C(═O)NHR⁰, —C(═O)NR⁰R⁰⁰, —SO₃R⁰, —SO₂R⁰, an alkyl group with 1 to 20 carbon atoms, or an aryl group with 6 to 20 carbon atoms, which may optionally be substituted by —F, —C, —NO₂, —CN, —NC, —NCO, —NCS, —OCN, —SCN, —OH, —R⁰, —OR⁰, —SR⁰, —C(═O)—R⁰, —C(═O)—OR⁰, —O—C(═O)—R⁰, —NH₂, —NHR⁰, NR⁰R⁰⁰, —O—C(═O)—OR⁰, —C(═O)—NHR⁰, or —C(═O)—NR⁰R⁰⁰; and
R⁰ and R⁰⁰ are defined as in claim 5.

7. The monomer composition according to claim 1, further comprising:
(c) a third siloxane monomer;
wherein the third siloxane monomer is different from the first siloxane monomer and the second siloxane monomer.

8. The monomer composition according to claim 7, wherein the third siloxane monomer is represented by one of the following Structures T1 to T5: 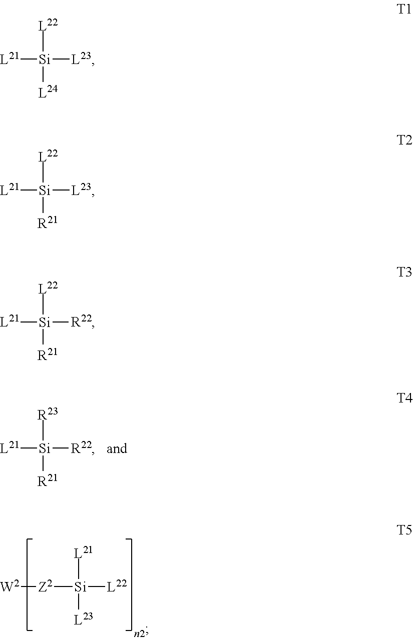
wherein:
L²¹, L²², L²³, and L²⁴ are the same or different from each other and each independently is selected from OR″ and halogen;
R″ is selected from the group consisting of straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C═C—, and wherein one or more H atoms are optionally replaced by F;
R²¹, R²² and R²³ are the same or different from each other and each independently is selected from the group consisting of H, straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, which optionally contain one or more functional groups selected from —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CR⁰═CR⁰⁰₂—, —CY¹═CY²—, and —C═C—, and
wherein one or more H atoms are optionally replaced by F;
Z² denotes a straight-chain alkylene group having 1 to 20 carbon atoms, a branched-chain alkylene group having 3 to 20 carbon atoms or a cyclic alkylene group having 3 to 20 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C═C—, and in which one or more H atoms are optionally replaced by F;
W² denotes a divalent, trivalent or tetravalent organic moiety;
and
n2=2, 3 or 4.

9. The monomer composition according to claim 7, further comprising:
(d) a fourth siloxane monomer;
wherein the fourth siloxane monomer is different from the first siloxane monomer, the second siloxane monomer and the third siloxane monomer.

10. The monomer composition according to claim 9, wherein the fourth siloxane monomer is represented by one of the following Structures F1 to F5: 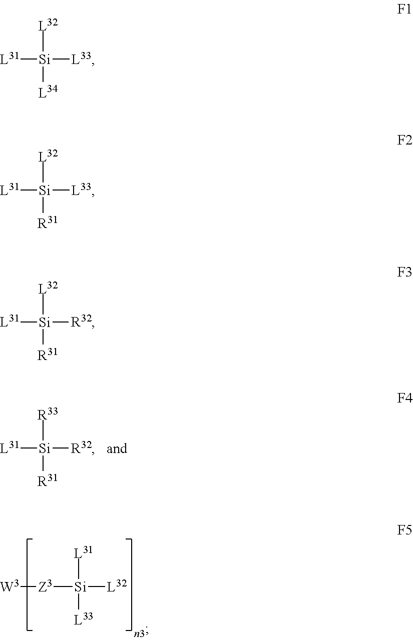
wherein:
L³¹, L³², L³³, and L³⁴ are the same or different from each other and each independently is selected from OR′″ and halogen;
R′″ is selected from the group consisting of straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, wherein one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C≡C—, and wherein one or more H atoms are optionally replaced by F;
R³¹, R³² and R³³ are the same or different from each other and each independently is selected from the group consisting of H, straight-chain alkyl having 1 to 30 carbon atoms, branched-chain alkyl having 3 to 30 carbon atoms, cyclic alkyl having 3 to 30 carbon atoms, and aryl having 6 to 20 carbon atoms, which optionally contain one or more functional groups selected from —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CR⁰═CR⁰⁰₂—, —CY¹═CY²—, and —C═C—, and wherein one or more H atoms are optionally replaced by F;
Z³ denotes a straight-chain alkylene group having 1 to 20 carbon atoms, a branched-chain alkylene group having 3 to 20 carbon atoms or a cyclic alkylene group having 3 to 20 carbon atoms, in which one or more non-adjacent and non-terminal CH₂ groups are optionally replaced by —O—, —S—, —C(═O)—, —C(═S)—, —C(═O)—O—, —O—C(═O)—, —NR⁰—, —SiR⁰R⁰⁰—, —CF₂—, —CR⁰═CR⁰⁰—, —CY¹═CY²— or —C═C—, and in which one or more H atoms are optionally replaced by F;
W³ denotes a divalent, trivalent and tetravalent organic moiety;
R⁰, R⁰⁰, Y¹, and Y² are defined as in claim 9; and
n3=2, 3 or 4.

11. The monomer composition according to claim 1,
wherein the molar ratio between the first siloxane monomer and the entirety of all further siloxane monomers is in the range from 1:0.1 to 1:10.

12. A method for preparing a siloxane oligomer or polymer, wherein the method comprises:
(i) providing a monomer composition according to claim 1; and
(ii) reacting the monomer composition provided in step (i) to obtain a siloxane oligomer or polymer.

13. A siloxane oligomer or polymer, obtainable by the method according to claim 12.

14. A siloxane oligomer or polymer, comprising or consisting of a first repeating unit, wherein the first repeating unit is derived from a first siloxane monomer,
wherein the first siloxane monomer comprises a substituted or unsubstituted maleimide group.

15. The siloxane oligomer or polymer according to claim 14, comprising a first repeating unit and a second repeating unit,
wherein the first repeating unit is derived from a first siloxane monomer and the second repeating unit is derived from a second siloxane monomer, wherein the first siloxane monomer comprises a substituted or unsubstituted maleimide group; and
wherein the second siloxane monomer is different from the first siloxane monomer.

16. The siloxane oligomer or polymer according to claim 15, further comprising a third repeating unit, wherein the third repeating unit is derived from a third siloxane monomer, wherein the third siloxane monomer is different from the first siloxane monomer and the second siloxane monomer.

17. The siloxane oligomer or polymer according to claim 16, further comprising a fourth repeating unit, wherein the fourth repeating unit is derived from a fourth siloxane monomer, wherein the fourth siloxane monomer is different from the first siloxane monomer, the second siloxane monomer and the third siloxane monomer.

18. A crosslinkable composition comprising one or more siloxane oligomers or polymers according to claim 13.

19. A method for manufacturing a microelectronic structure comprising:
(1) applying a crosslinkable composition according to claim 18 to a surface of a substrate; and
(2) curing said crosslinkable composition to form a layer which passivates and optionally planarizes the surface of the substrate.

20. An electronic device comprising a microelectronic structure, obtainable by the method for manufacturing according to claim 19.
